(19) United States
(12) Patent Application Publication
(10) Pub. No.: US 2022/0352250 A1
(43) Pub. Date: Nov. 3, 2022

(54) DISPLAY DEVICE

(71) Applicant: SAMSUNG DISPLAY CO., LTD., Yongin-si (KR)

(72) Inventors: Joo Woan CHO, Seongnam-si (KR); Ki Seong SEO, Seoul (KR); Byung Choon YANG, Seoul (KR); Tae Hee LEE, Hwaseong-si (KR); Hae Yun CHOI, Hwaseong-si (KR)

(21) Appl. No.: 17/698,485

(22) Filed: Mar. 18, 2022

(30) Foreign Application Priority Data
Apr. 29, 2021 (KR) 10-2021-0055967

(51) Int. Cl. H01L 27/15; H01L 33/50; H01L 33/62; H01L 33/64

(52) U.S. Cl. CPC H01L 27/156; H01L 33/50; H01L 33/62; H01L 33/647

(57) ABSTRACT

A display device is provided. The display device comprises a first substrate including a display area, and a non-display area surrounding the display area, light emitting elements in the display area on the first substrate, pads in the non-display area, and a circuit board including circuit board pads connected to the pads, and including a first cover layer facing the first substrate, and defining first opening holes formed to correspond to the circuit board pads, a metal layer on the first cover layer and having the circuit board pads therebelow, and a second cover layer on the metal layer, and defining second opening holes exposing a portion of the metal layer.

### CROSS-REFERENCE TO RELATED APPLICATION

This application claims priority to, and the benefit of, Korean Patent Application No. 10-2021-0055967 filed on Apr. 29, 2021 in the Korean Intellectual Property Office, the contents of which in its entirety are herein incorporated by reference.

### BACKGROUND

### 1. Field

The disclosure relates to a display device.

### 2. Description of the Related Art

As the information society develops, demands for display devices for displaying images are increasing in various forms. The display devices may be flat panel displays, such as liquid crystal displays, field emission displays, and light emitting displays. The light emitting displays may include an organic light emitting display including an organic light emitting diode element as a light emitting element and an inorganic light emitting display including an inorganic semiconductor element as a light emitting element.

Recently, a head-mounted display including a light emitting display has been developed. The head-mounted display is a virtual reality (VR) or augmented reality (AR) glasses-type monitor device that is worn by a user in the form of glasses or a helmet and forms a focus at a short distance in front of the eyes.

### SUMMARY

Aspects of the disclosure provide an ultra-high resolution display device including inorganic light emitting elements, and including a larger number of emission areas per unit area.

Aspects of the disclosure provide a display device in which a likelihood of damage to a circuit board during bonding between the circuit board and a pad of a display substrate is reduced prevented.

A display device according to some embodiments includes a plurality of opening holes formed in a cover layer in which a circuit board covers wires. The plurality of opening holes may be formed to correspond to a plurality of pads, and may be formed on the other surface opposite to one surface where the pads are located.

In the display device, the process of bonding the pads of the circuit board and the pads of the display substrate may be performed by a laser bonding process, and it is possible to reduce or prevent the likelihood of damage to the cover layer covering the wires of the circuit board due to irradiating laser through the opening hole formed in the circuit board.

However, aspects of the disclosure are not restricted to those set forth herein. The above and other aspects of the disclosure will become more apparent to one of ordinary skill in the art to which the disclosure pertains by referencing the detailed description of the disclosure given below.

According to some embodiments of the disclosure, a display device including a first substrate including a display area, and a non-display area surrounding the display area, light emitting elements in the display area on the first substrate, pads in the non-display area, and a circuit board including circuit board pads connected to the pads, and including a first cover layer facing the first substrate, and defining first opening holes formed to correspond to the circuit board pads, a metal layer on the first cover layer and having the circuit board pads therebelow, and a second cover layer on the metal layer, and defining second opening holes exposing a portion of the metal layer.

The pads may include pad base layers, and pad upper layers respectively on the pad base layers, wherein the circuit board pads are respectively integrated with the pad upper layers.

The display device may further include patterns corresponding to the second opening holes, and overlapping the circuit board pads on the metal layer.

The patterns may be in the second opening holes, respectively.

The display device may further include a heat transfer pattern corresponding to the second opening holes, and directly contacting the metal layer.

The display device may further include patterns on a portion of the heat transfer pattern overlapping the circuit board pads.

The circuit board may define pin holes corresponding to the second opening holes, and penetrating the metal layer and the circuit board pads.

The display device may further include patterns on portions of the pad upper layers overlapping the pin holes, respectively, wherein the pads and the circuit board pads are integrated with each other at a peripheral portion of the pin holes, respectively.

The display device may further include common electrodes in the non-display area on the first substrate, and electrically connected to the light emitting elements, respectively, wherein the pads respectively include first pads at outer sides of the common electrodes, and second pads at inner sides of the common electrodes in the non-display area, wherein the first substrate defines first via holes penetrating therethrough, and respectively corresponding to the first pads, and also defines second via holes respectively corresponding to the second pads, and wherein the display device further includes first pad connection electrodes respectively connected to the first pads and to first circuit board pads of the circuit board pads, and second pad connection electrodes respectively connected to the second pads and to second circuit board pads of the circuit board pads.

The circuit board may be below the first substrate, wherein the first pad connection electrodes include first connection portions in the first via holes, respectively, and first electrode portions below the first substrate, wherein the second pad connection electrodes include second connection portions in the second via holes, respectively, and second electrode portions below the first substrate, wherein the first circuit board pads are integrated with the first electrode portions, respectively, and wherein the second circuit board pads are integrated with the second electrode portions, respectively.

The display device may further include a heat dissipation substrate below the first substrate, and located across the display area and the non-display area.

The circuit board may further include a heat dissipation layer below the first substrate, and located between the first substrate and the circuit board in the display area.

The light emitting elements may include first semiconductor layers, active layers on the first semiconductor layers, and second semiconductor layers on the active layers, wherein the display device further includes a third semiconductor layer on the first substrate, and having the second semiconductor layers of the light emitting elements thereon, and common electrodes on the second semiconductor layers, respectively.

The second semiconductor layers of the light emitting elements may be connected to each other through a base layer in the display area and the non-display area on the third semiconductor layer, wherein the display device further includes first connection electrodes respectively between the light emitting elements and the first substrate in the display area, and second connection electrodes respectively between the common electrodes and the second semiconductor layers in the non-display area.

According to some embodiments of the disclosure, a display device including a first substrate including a display area on which light emitting elements are located, and a non-display area surrounding the display area, common electrodes surrounding the display area in the non-display area, and spaced apart from each other, pads spaced apart from the common electrodes in the non-display area, and a circuit board including circuit board pads on the first substrate, and electrically connected to the pads, respectively, cover layers, and a metal layer between the cover layers, and having the circuit board pads therebelow, wherein the cover layers define opening holes exposing respective portions of the metal layer.

The display device may further include patterns in the opening holes, and overlapping the circuit board pads.

The patterns may be in one of the opening holes.

The circuit board may be on the first substrate on which the light emitting elements are located, wherein the circuit board pads are respectively integrated with the pads.

The circuit board may be below the first substrate, wherein the pads are respectively electrically connected to the circuit board pads through pad connection electrodes in via holes penetrating the first substrate.

The pad connection electrodes may respectively include connection portions in the via holes, and electrode portions respectively connected to the connection portions and located below the first substrate, wherein the circuit board pads are respectively integrated with the electrode portions of the pad connection electrodes.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to some embodiments;

FIG. 2 is a plan view of part A of FIG. 1;

FIG. 3 is a plan view of part B of FIG. 2;

FIG. 4 is a cross-sectional view taken along the line L1-L1′ of FIG. 2;

FIG. 5 is a cross-sectional view showing a light emitting element according to some embodiments;

FIG. 6 is a plan view showing the arrangement of light emitting elements of a display device according to some embodiments;

FIG. 7 is a plan view showing the arrangement of color filters of a display device according to some embodiments;

FIG. 8 is a plan view showing the region where circuit board pads of a display device according to some embodiments are located;

FIG. 9 is a cross-sectional view taken along the line L2-L2′ of FIG. 8;

FIG. 10 is a cross-sectional view taken along the line L3-L3′ of FIG. 8;

FIG. 11 is a schematic view showing a process of bonding pads and circuit board pads during the manufacturing process of a display device according to some embodiments;

FIG. 12 is a plan view showing the region where the circuit board pads of a display device according to other embodiments are located;

FIG. 13 is a cross-sectional view taken along the line L4-L4′ of FIG. 12;

FIG. 14 is a cross-sectional view showing the portion where the circuit board and the pad of a display device according to other embodiments are located;

FIG. 15 is a plan view showing the region where the circuit board pads of a display device according to still other embodiments are located;

FIG. 16 is a cross-sectional view taken along the line L5-L5′ of FIG. 15;

FIG. 17 is a cross-sectional view showing the portion where the pads and the circuit board pads of a display device according to still other embodiments are located;

FIG. 18 is a cross-sectional view illustrating a part of a display device according to still other embodiments;

FIG. 19 is a cross-sectional view illustrating a part of a display device according to other embodiments;

FIGS. 20 to 22 are schematic views showing a device including a display device according to some embodiments; and

FIGS. 23 and 24 show a transparent display device including a display device according to some embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

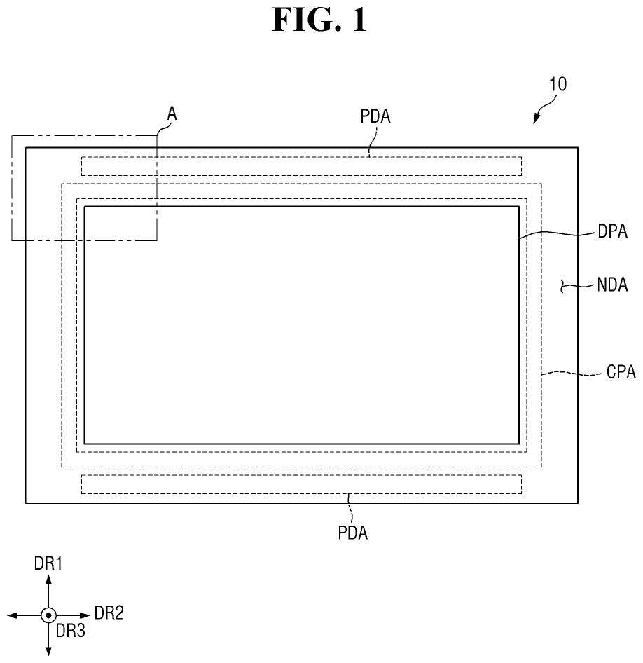

FIG. 1 is a schematic plan view of a display device according to some embodiments.

Referring to FIG. 1, a display device 10 displays a moving image or a still image. The display device 10 may refer to any electronic device provided with a display screen. Examples of the display device 10 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder, and the like, which provide a display screen.

The display device 10 includes a display panel that provides a display screen. Examples of the display panel may include an inorganic light emitting diode display panel, an organic light emitting display panel, a quantum dot light emitting display panel, a plasma display panel and a field emission display panel. In the following description, a display device in which inorganic light emitting diodes are located on a semiconductor circuit board is illustrated as an example of the display panel. However, the disclosure is not limited thereto, and may be applied to another display panel as long as the same technical spirit may be applied.

The shape of the display device 10 may be variously modified. For example, the display device 10 may have a shape, such as a rectangular shape elongated in a horizontal direction, a rectangular shape elongated in a vertical direction, a square shape, a quadrilateral shape with rounded corners (vertices), another polygonal shape, and a circular shape. The shape of a display area DPA of the display device 10 may also be similar to the overall shape of the display device 10. FIG. 1 illustrates a display device 10 having a rectangular shape elongated in a second direction DR2.

The display device 10 may include the display area DPA and a non-display area NDA. The display area DPA is an area where an image can be displayed, and the non-display area NDA is an area where a screen is not displayed. The display area DPA may also be referred to as an active region, and the non-display area NDA may also be referred to as a non-active region. The display area DPA may substantially occupy the center of the display device 10.

The non-display area NDA may be located around the display area DPA. The non-display area NDA may completely or partially surround the display area DPA. The display area DPA may have a rectangular shape, and the non-display area NDA may be located adjacent to four sides of the display area DPA. The non-display area NDA may form a bezel of the display device 10. Wires or circuit drivers included in the display device 10 may be located in the non-display area NDA, or external devices may be mounted on the non-display area NDA.

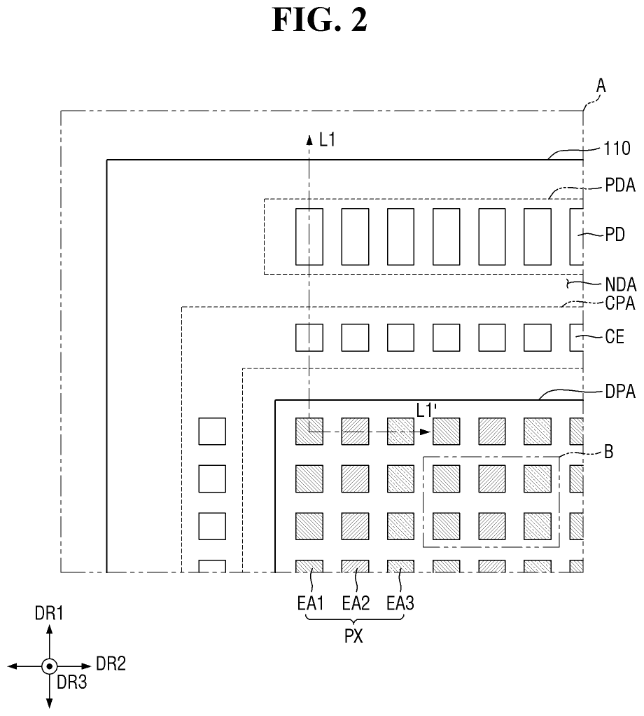

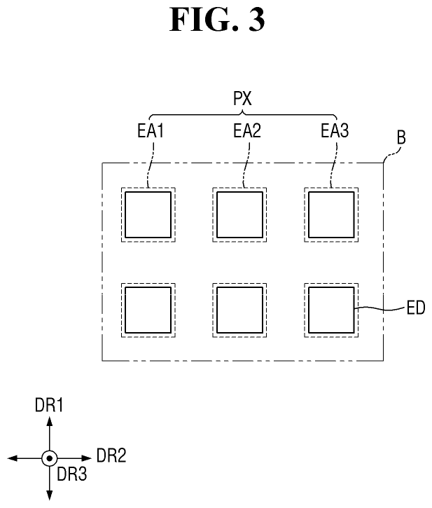

For example, the non-display area NDA may include a plurality of pad areas PDA and a common electrode connection portion CPA. The common electrode connection portion CPA may surround the display area DPA, and the plurality of pad areas PDA may be located in a shape extending in one direction (e.g., in the second direction DR2) on one side of the common electrode connection portion CPA. A plurality of pads PD (see FIG. 2) electrically connected to an external device are located in the pad area PDA, and a common electrode CE (see FIG. 2), which is electrically connected to a plurality of light emitting elements ED (see FIG. 3) located in the display area DPA, is located at the common electrode connection portion CPA. In the drawing, the pad areas PDA, which are located at respective sides with respect to a first direction DR1 of the display area DPA, are illustrated as being located at the outer side of the common electrode connection portion CPA in the non-display area NDA. However, the disclosure is not limited thereto, and a greater or fewer number of pad areas PDA may be used in other embodiments. Further, in some embodiments, a display device 10 may further include a pad area PDA located in an inner non-display area that is located at the inside of the common electrode connection portion CPA in the non-display area NDA.

FIG. 2 is a plan view of part A of FIG. 1. FIG. 3 is a plan view of part B of FIG. 2. FIG. 2 is an enlarged view of a part of each of the display area DPA, the pad area PDA, and the common electrode connection portion CPA of the display device 10, and FIG. 3 shows the planar arrangement of some pixels PX in the display area DPA.

Referring to FIGS. 2 and 3, the display area DPA of the display device 10 may include a plurality of pixels PX. The plurality of pixels PX may be arranged in a matrix. The shape of each pixel PX may be a rectangular or square shape in a plan view. However, the disclosure is not limited thereto, and it may be a rhombic shape in which each side is inclined with respect to one direction. The pixels PX may be arranged in a stripe type or in an island type. In addition, each of the pixels PX may include one or more light emitting elements that emit light of a specific wavelength band to display a specific color.

Each of the plurality of pixels PX may include a plurality of emission areas EA1, EA2, and EA3. In the display device 10, one pixel PX including the plurality of emission areas EA1, EA2, and EA3 may be a minimum light emitting unit.

For example, one pixel PX may include a first emission area EA1, a second emission area EA2, and a third emission area EA3. The first emission area EA1 may emit light of a first color, the second emission area EA2 may emit light of a second color, and the third emission area EA3 may emit light of a third color. For example, the first color may be red, the second color may be green, and the third color may be blue. However, the disclosure is not limited thereto, and the emission areas EA1, EA2, and EA3 may emit light of the same color. In some embodiments, one pixel PX may include three emission areas EA1, EA2, and EA3, but the disclosure is not limited thereto. For example, one pixel PX may include four or more emission areas.

Each of the plurality of emission areas EA1, EA2, and EA3 may include a light emitting element ED that emits light of a specific color. Although the light emitting element ED having a quadrilateral planar shape is illustrated, the present disclosure is not limited thereto. For example, the light emitting element ED may have a polygonal shape other than a quadrilateral shape, a circular shape, an elliptical shape, or an atypical shape.

The plurality of emission areas EA1, EA2, and EA3 may be arranged in the first direction DR1 and the second direction DR2, and the first emission area EA1, the second emission area EA2, and the third emission area EA3 may be arranged alternately, or sequentially, in the second direction DR2, and such arrangement may be repeated. Further, the first emission area EA1, the second emission area EA2, and the third emission area EA3 may be, respectively, repeatedly arranged in the first direction DR1.

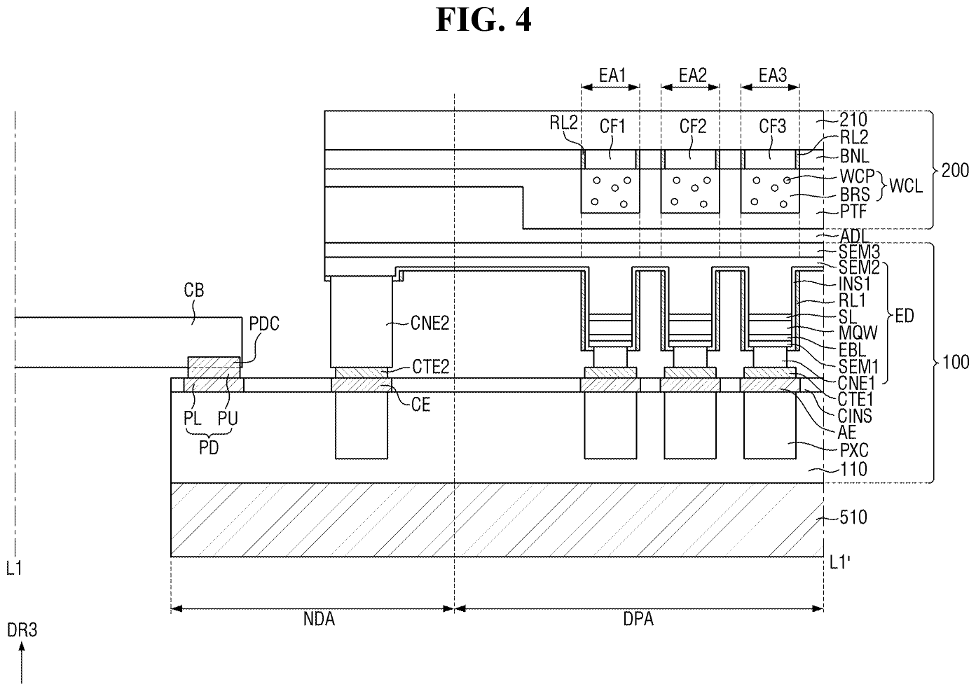

The display device 10 may include a bank layer BNL (see FIG. 4) surrounding the plurality of emission areas EA1, EA2, and EA3, and the bank layer BNL may distinguish different emission areas EA1, EA2, and EA3. The bank layer BNL may surround the light emitting element ED while being spaced apart from the light emitting element ED in a plan view. The bank layer BNL may include portions extending in the first direction DR1 and the second direction DR2 to form a mesh, net, or lattice-shaped pattern in a plan view.

Although it is illustrated in FIGS. 2 and 3 that each of the emission areas EA1, EA2, and EA3 surrounded by the bank layer BNL has a quadrilateral shape in a plan view, the disclosure is not limited thereto. The planar shape of each of the emission areas EA1, EA2, and EA3 may be variously modified depending on the planar arrangement of the bank layer BNL.

A plurality of common electrodes CE may be located at the common electrode connection portion CPA of the non-display area NDA. The plurality of common electrodes CE may be spaced apart from each other while surrounding the display area DPA. The common electrode CE may be electrically connected to the plurality of light emitting elements ED located in the display area DPA. Further, the common electrode CE may be electrically connected to the semiconductor circuit board.

Although it is illustrated in the drawing that the common electrode connection portion CPA is located to surround, or be adjacent to, both sides, or respective sides, with respect to the first direction DR1 and the second direction DR2 of the display area DPA, the disclosure is not limited thereto. The planar arrangement of the common electrode connection portion CPA may vary depending on the arrangement of the common electrodes CE. For example, when the common electrodes CE are arranged in one direction on one side of the display area DPA, the planar arrangement of the common electrode connection portion CPA may have a shape extending in one direction.

The plurality of pads PD may be located in the pad area PDA. Each of the pads PD may be electrically connected to a circuit board pad PDC (see FIG. 4) located at an external circuit board CB (see FIG. 4). The plurality of pads PD may be spaced apart from each other in the second direction DR2 in the pad area PDA.

The arrangement of the pads PD may be designed depending on the number of light emitting elements ED located in the display area DPA, and/or depending on the arrangement of wires electrically connected thereto. The arrangement of the pads PD may be variously modified depending on the arrangement of the light emitting elements ED and the arrangement of the wires electrically connected thereto.

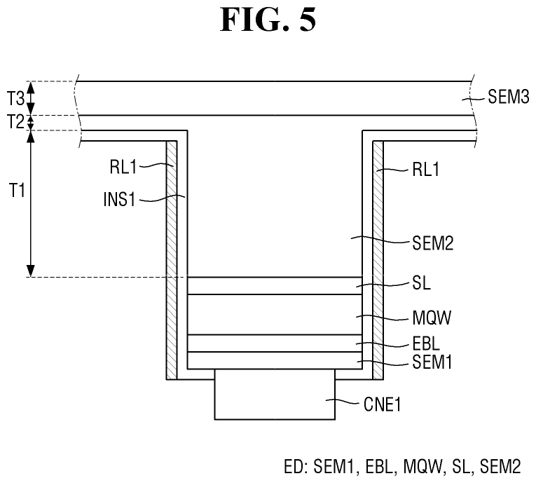

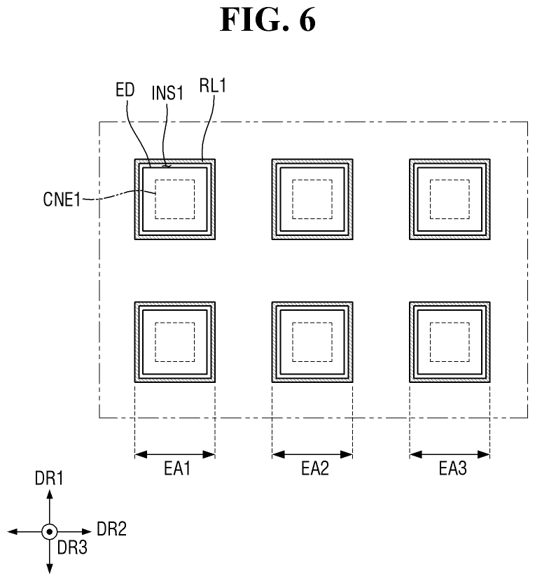

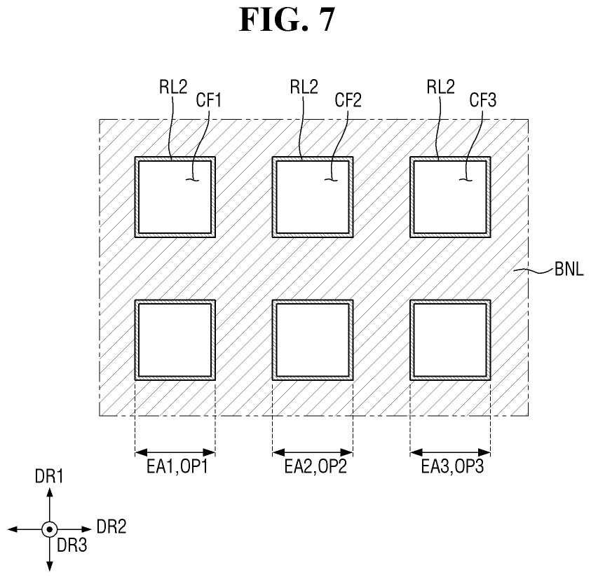

FIG. 4 is a cross-sectional view taken along the line L1-L1′ of FIG. 2. FIG. 5 is a cross-sectional view showing a light emitting element according to some embodiments. FIG. 6 is a plan view showing the arrangement of light emitting elements of a display device according to some embodiments. FIG. 7 is a plan view showing the arrangement of color filters of a display device according to some embodiments. FIG. 4 shows a cross section across the pad area PDA, the common electrode connection portion CPA, and one pixel PX of the display area DPA.

Referring to FIGS. 4 to 7 in conjunction with FIGS. 1 to 3, the display device 10 according to some embodiments may include a display substrate 110, a color conversion substrate 200, and the circuit board CB. Further, the display device 10 may further include a heat dissipation substrate 510 located below the display substrate 100.

The display substrate 100 may include a first substrate 110, the plurality of light emitting elements ED located on the first substrate 110, the plurality of pads PD, and electrode connection portions CTE1 and CTE2. The color conversion substrate 200 may include a second substrate 210, color filters CF1, CF2, and CF3 located on the second substrate 210, and a color control structure WCL. The circuit board CB may include a circuit board pad PDC electrically connected to the plurality of pads PD of the display substrate 100, and may be partially located on the first substrate 110.

The first substrate 110 may be a semiconductor circuit substrate. The first substrate 110 that is a silicon wafer substrate formed by a semiconductor process may include a plurality of pixel circuit units PXC. Each of the pixel circuit units PXC may be formed by the process of forming a semiconductor circuit on a silicon wafer. Each of the plurality of pixel circuit units PXC may include at least one transistor and at least one capacitor formed by the semiconductor process. For example, the plurality of pixel circuit units PXC may include a CMOS circuit.

The plurality of pixel circuit units PXC may be located in the display area DPA and in the non-display area NDA. Among the plurality of pixel circuit units PXC, each of the pixel circuit units PXC located in the display area DPA may be electrically connected to a pixel electrode AE. The plurality of pixel circuit units PXC located in the display area DPA may correspond to a plurality of pixel electrodes AE, respectively, and may overlap the light emitting elements ED located in the display area DPA in a third direction DR3, which is a thickness direction.

Among the plurality of pixel circuit units PXC, each of the pixel circuit units PXC located in the non-display area NDA may be electrically connected to the common electrode CE. The plurality of pixel circuit units PXC located in the non-display area NDA may correspond to the plurality of common electrodes CE, respectively, and may overlap, in the third direction DR3, the common electrode CE and a second connection electrode CNE2 that are located in the non-display area NDA.

A circuit insulating layer CINS may be located on the plurality of pixel circuit units PXC. The circuit insulating layer CINS may protect the plurality of pixel circuit units PXC, and may flatten the stepped portions of the plurality of pixel circuit units PXC. The circuit insulating layer CINS may expose a part of each of the pixel electrodes AE to electrically connect the pixel electrodes AE to first connection electrodes CNE1. The circuit insulating layer CINS may include an inorganic insulating material, such as silicon oxide (SiOₓ), silicon nitride (SiNₓ), silicon oxynitride (SiOₓN_{y}), aluminum oxide (AlO_{z}), and aluminum nitride (AlNₓ).

The plurality of pixel electrodes AE may be located in the display area DPA, and each of them may be located on the pixel circuit unit PXC corresponding thereto. Each of the pixel electrodes AE may be an exposed electrode that is formed integrally with the pixel circuit unit PXC, and may be exposed from the pixel circuit unit PXC. The plurality of common electrodes CE may be located at the common electrode connection portion CPA in the non-display area NDA, and each of them may be located on the pixel circuit unit PXC corresponding thereto. The common electrode CE may be an exposed electrode that is formed integrally with the pixel circuit unit PXC and exposed from the pixel circuit unit PXC. Each of the pixel electrode AE and the common electrode CE may contain a metal material such as aluminum (Al).

Each of a plurality of electrode connection portions CTE1 and CTE2 may be located on the pixel electrode AE or the common electrode CE. Each of the first electrode connection portions CTE1 may be located on the pixel electrode AE in the display area DPA. The first electrode connection portions CTE1 may correspond to different pixel electrodes AE. Each of the second electrode connection portions CTE2 may be located at the common electrode connection portion CPA in the non-display area NDA to surround the display area DPA, and may be located on the common electrode CE.

For example, each of the electrode connection portions CTE1 and CTE2 may be directly located on the pixel electrode AE or the common electrode CE to be in contact therewith. Each of the electrode connection portions CTE1 and CTE2 may be electrically connected to the pixel electrode AE or the common electrode CE, and the light emitting element ED. Further, the second electrode connection portion CTE2 may be electrically connected to any one of the plurality of pads PD through the pixel circuit unit PXC formed in the non-display area NDA.

Each of the electrode connection portions CTE1 and CTE2 may contain a material that allows electrical connection with the pixel electrode AE or the common electrode CE, and with the light emitting elements ED. For example, each of the electrode connection portions CTE1 and CTE2 may contain at least one of gold (Au), copper (Cu), aluminum (Al), or tin (Sn). Alternatively, each of the electrode connection portions CTE1 and CTE2 may include a first layer containing any one of gold (Au), copper (Cu), aluminum (Al), and tin (Sn), and a second layer containing another one of gold (Au), copper (Cu), aluminum (Al), and tin (Sn).

The plurality of pads PD are located in the pad area PDA in the non-display area NDA. The plurality of pads PD are spaced apart from the common electrode CE and the second electrode connection portion CTE2. The plurality of pads PD may be spaced apart from the common electrode CE toward the outer side of the non-display area NDA.

Each of the pads PD may include a pad base layer PL and a pad upper layer PU. The pad base layer PL may be located on the first substrate 110, and the circuit insulating layer CINS may expose the pad base layer PL. The pad upper layer PU may be directly located on the pad base layer PL.

Each of the plurality of pads PD may be electrically connected to the circuit board pad PDC of the circuit board CB. In accordance with some embodiments, the plurality of pads PD may be integrated with, and bonded to, the circuit board pad PDC by a laser bonding process. The pads PD and the circuit board pads PDC may be bonded to each other by laser irradiated from the surface that is opposite to the surface of the circuit board CB where the circuit board pad PDC is located. The laser irradiated from the other surface of the circuit board CB may transfer heat to the circuit board pad PDC, and the pad PD and the circuit board pad PDC may be melted and integrated by the heat. A detailed description thereof will be given later with further reference to other drawings.

The circuit board CB may be a flexible printed circuit board (FPCB), a printed circuit board (PCB), a flexible printed circuit (FPC), or a flexible film, such as a chip on film (COF).

The plurality of light emitting elements ED may respectively correspond to the emission areas EA1, EA2, and EA3 in the display area DPA. One light emitting element ED may correspond to one of the emission areas EA1, EA2, and EA3.

The light emitting element ED may be located on the first electrode connection portion CTE1 in the display area DPA. The light emitting element ED may be an inorganic light emitting diode having a shape extending in one direction. The light emitting element ED may have a cylindrical shape that is longer in a width than in a height, may have a disc shape, or may have a rod shape. However, the disclosure is not limited thereto, and the light emitting element ED may have various shapes, such as a rod shape, a wire shape, a tube shape, a polygonal prism shape, such as a regular cube, a rectangular parallelepiped, and a hexagonal prism, or a shape extending in one direction and having a partially inclined outer surface. For example, the light emitting element ED may have the length in the extension direction, or the length in the third direction DR3, that is longer than the width in the horizontal direction, and the length in the third direction DR3 of the light emitting element ED may be about 1 μm to about 5 μm.

In accordance with some embodiments, the light emitting element ED may include the first connection electrode CNE1, a first semiconductor layer SEM1, an electron blocking layer EBL, an active layer MQW, a superlattice layer SL, and a second semiconductor layer SEM2. The first connection electrode CNE1, the first semiconductor layer SEM1, the electron blocking layer EBL, the active layer MQW, the superlattice layer SL, and the second semiconductor layer SEM2 may be sequentially stacked in the third direction DR3.

The first connection electrode CNE1 may be located on the first electrode connection portion CTE1. The first connection electrode CNE1 may be in direct contact with the first electrode connection portion CTE1, and may transmit the light emitting signal applied to the pixel electrode AE to the light emitting element ED. The first connection electrode CNE1 may be an ohmic connection electrode. However, the disclosure is not limited thereto, and it may be a Schottky connection electrode in some embodiments. The light emitting element ED may include at least one first connection electrode CNE1.

When the light emitting element ED is electrically connected to the electrode connection portions CTE1 and CTE2, the first connection electrode CNE1 may reduce a resistance due to the contact between the light emitting element ED and the electrode connection portions CTE1 and CTE2. The first connection electrode CNE1 may contain a conductive metal. For example, the first connection electrode CNE1 may include at least one of gold (Au), copper (Cu), tin (Sn), titanium (Ti), aluminum (Al), or silver (Ag). For example, the first connection electrode CNE1 may contain a 9:1 alloy, a 8:2 alloy or a 7:3 alloy of gold and tin, or may contain an alloy (e.g., SAC305) of copper, silver, and tin.

The first semiconductor layer SEM1 may be located on the first connection electrode CNE1. The first semiconductor layer SEM1 may be a p-type semiconductor, and may include a semiconductor material having a chemical formula of AlxGayIn1-x-yN (0≤x≤1, 0≤y≤1, 0≤x+y≤1). For example, it may be any one or more of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg.

The electron blocking layer EBL may be located on the first semiconductor layer SEM1. The electron blocking layer EBL may reduce or prevent electrons flowing into the active layer MQW from being injected into another layer without being recombined with holes in the active layer MQW. For example, the electron blocking layer EBL may be p-AlGaN doped with p-type Mg. The thickness of the electron blocking layer EBL may be within a range of about 10 nm to about 50 nm, but the disclosure is not limited thereto. In some embodiments, the electron blocking layer EBL may be omitted.

The active layer MQW may be located on the electron blocking layer EBL. The active layer MQW may emit light due to recombination of the electrons and the holes in response to the light emitting signal applied through the first semiconductor layer SEM1 and the second semiconductor layer SEM2. In some embodiments, the light emitting element ED of the display device 10 may emit light of a third color (e.g., blue light), in which the active layer MQW has a central wavelength band of about 450 nm to about 495 nm.

The active layer MQW may include a material having a single or multiple quantum well structure. When the active layer MQW contains a material having a multiple quantum well structure, the active layer MQW may have the structure in which a plurality of well layers and barrier layers are alternately laminated. At this time, the well layer may be formed of InGaN, and the barrier layer may be formed of GaN or AlGaN, but the disclosure is not limited thereto.

For example, the active layer MQW may have a structure in which semiconductor materials having large band gap energy and semiconductor materials having small band gap energy are alternately stacked, and may include other group III to V semiconductor materials according to the wavelength band of the emitted light. The light emitted from the active layer MQW is not limited to the blue light of the third color. In some cases, red light of the first color or green light of the second color may be emitted.

The superlattice layer SL is located on the active layer MQW. The superlattice layer SL may reduce stress due to the difference in lattice constant between the second semiconductor layer SEM2 and the active layer MQW. For example, the superlattice layer SL may be formed of InGaN or GaN. The thickness of the superlattice layer SL may be about 50 nm to about 200 nm. However, the superlattice layer SL may be omitted.

The second semiconductor layer SEM2 may be located on the superlattice layer SL. The second semiconductor layer SEM2 may be an n-type semiconductor. The second semiconductor layer SEM2 may include a semiconductor material having a chemical formula of AlxGayIn1-x-yN (0≤x≤1, 0≤y≤1, 0≤x+y≤1). For example, it may be any one or more of n-type doped AlGaInN, GaN, AlGaN, InGaN, AlN and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness of the second semiconductor layer SEM2 may be within a range of about 2 μm to about 4 μm, but the disclosure is not limited thereto.

In accordance with some embodiments, the second semiconductor layers SEM2 of the plurality of light emitting elements ED of the display device 10 may be connected to each other. The plurality of light emitting elements ED may share a part of the second semiconductor layer SEM2 as one common layer, and the plurality of layers located on the second semiconductor layer SEM2 may be spaced apart from each other. The second semiconductor layer SEM2 may include a base layer located in the display area DPA and a part of the non-display area NDA while extending in the first direction DR1 and the second direction DR2, and a plurality of protrusions partially protruding from the base layer and spaced apart from each other. The layers of the light emitting element ED may be formed as patterns located on the protrusion of the second semiconductor layer SEM2 and spaced apart from each other, and they may form one light emitting element ED together with the protrusion of the second semiconductor layer SEM2. A thickness T1 of the protrusion of the second semiconductor layer SEM2 forming a part of the light emitting element ED may be greater than a thickness T2 of the base layer that does not overlap the first semiconductor layer SEM1.

Further, in the display device 10, the second semiconductor layer SEM2 may transmit the light emitting signal applied through the second connection electrode CNE2 and the second electrode connection portion CTE2 to the plurality of light emitting elements ED. As will be described later, the second connection electrode CNE2 may be located on (e.g., below) one surface of the base layer of the second semiconductor layer SEM2 of the plurality of light emitting elements ED that is located in the non-display area NDA, and may be electrically connected to the common electrode CE through the second electrode connection portion CTE2.

The third semiconductor layer SEM3 is located on the second semiconductor layer SEM2 of the light emitting elements ED. The third semiconductor layer SEM3 may be located in the display area DPA and in a part of the non-display area NDA, and the third semiconductor layer SEM3 may disposed on the entire base layer of the second semiconductor layer SEM2. The third semiconductor layer SEM3 may be an undoped semiconductor. The third semiconductor layer SEM3 may contain the same material as that of the second semiconductor layer SEM2, and may contain a material that is not doped with an n-type or p-type dopant. In some embodiments, the third semiconductor layer SEM3 may be, but is not limited to, at least one of undoped InAlGaN, GaN, AlGaN, InGaN, AlN, and InN.

Unlike the second semiconductor layer SEM2, the third semiconductor layer SEM3 may not have conductivity, and the light emitting signal applied to the pixel electrode AE and the common electrode CE may flow through the light emitting element ED and the second semiconductor layer SEM2. In the manufacturing process of the light emitting element ED, the second semiconductor layer SEM2 and the plurality of light emitting elements ED may be formed on the third semiconductor layer SEM3. A thickness T3 of the third semiconductor layer SEM3 may be smaller than the thickness T1 of the protrusion of the second semiconductor layer SEM2, and may be greater than the thickness T2 of the base layer of the second semiconductor layer SEM2.

A plurality of second connection electrodes CNE2 may be located at the common electrode connection portion CPA in the non-display area NDA. The second connection electrode CNE2 may be located on (e.g., below) one surface of the base layer of the second semiconductor layer SEM2. Further, the second connection electrode CNE2 may be directly located on the second electrode connection portion CTE2, and may transmit the light emitting signal applied from the common electrode CE to the light emitting element ED. The second connection electrode CNE2 may be made of the same material as that the first connection electrodes CNE1. The thickness of the second connection electrode CNE2 in the third direction DR3 may be greater than the thickness of the first connection electrode CNE1.

A first insulating layer INS1 may be located on (e.g., below) one surface of the base layer of the second semiconductor layer SEM2, and may be located on the side surfaces of the light emitting elements ED. The first insulating layer INS1 may surround at least the light emitting elements ED. The portions of the first insulating layer INS1 surrounding the light emitting elements ED respectively correspond to the light emitting elements ED, and thus may be spaced apart from each other in the first direction DR1 and the second direction DR2 in a plan view. The first insulating layer INS1 may protect each of the plurality of light emitting elements ED, and may insulate the second semiconductor layer SEM1, and the light emitting elements ED generally, from other layers. The first insulating layer INS1 may include an inorganic insulating material such as silicon oxide (SiOₓ), silicon nitride (SiNₓ), silicon oxynitride (SiOₓN_{y}), aluminum oxide (AlO_{y}), and aluminum nitride (AlNₓ).

A first reflective layer RL1 may surround the side surfaces of the plurality of light emitting elements ED. The first reflective layer RL1 may correspond to each of the emission areas EA1, EA2, and EA3 in the display area DPA, and may be directly on (e.g., directly next to) the first insulating layer INS1 on (e.g., next to) the side surface of the light emitting element ED. Because the first reflective layers RL1 surround the light emitting elements ED spaced apart from each other while corresponding thereto, different first reflective layers RL1 may be spaced apart from each other in the first direction DR1 and the second direction DR2 in a plan view. The first reflective layer RL1 may reflect the lights emitted from the active layer MQW of the light emitting element ED, and the lights may therefore travel toward the second substrate 210 instead of the first substrate 110.

The first reflective layer RL1 may contain a metal material having high reflectivity, such as aluminum (Al). The thickness of the first reflective layer RL1 may be about 0.1 μm, but is not limited thereto.

The heat dissipation substrate 510 may be located on, or below, the lower side of the display substrate 100, which is opposite to the upper side facing the color conversion substrate 200. The heat dissipation substrate 510 may substantially have a shape that is similar to that of the first substrate 110, and may be in contact with the lower side of the first substrate 110. In accordance with some embodiments, the heat dissipation substrate 510 may be located such that at least a part of the heat dissipation substrate 510 overlaps the display area DPA of the display device 10 in the thickness direction, and such that another part of the heat dissipation substrate 510 overlaps the non-display area NDA. The heat dissipation substrate 510 may contain a material having relatively high thermal conductivity, and thus may effectively release or conduct the heat generated by the display substrate 100 and the circuit board CB. For example, the heat dissipation substrate 510 may be made of a metal material having high thermal conductivity, such as tungsten (W), aluminum (Al), and copper (Cu).

However, the disclosure is not limited thereto. In the embodiments in which the circuit board CB is located below the first substrate 110, the heat dissipation substrate 510 may be located on the bottom surface of the circuit board CB. The heat dissipation substrate 510 need not be in direct contact with the first substrate 110, and instead may be in contact with the circuit board CB to release or conduct the heat generated by the display device 10. In addition, the heat dissipation substrate 510 may have a structure that is capable of effectively releasing the heat generated by the display device 10, for example the heat generated by the light emitting elements ED.

The color conversion substrate 200 may be located on the display substrate 100, and a protective layer PTF, the color control structure WCL, the color filters CF1, CF2, and CF3, a second reflective layer RL2, the bank layer BNL, and the second substrate 210 are located above the light emitting elements ED. In the following description, the layers located on one surface of the second substrate 210 facing the first substrate 110 will be sequentially described.

The second substrate 210 may face the first substrate 110. The second substrate 210 may be a base substrate supporting the plurality of layers included in the color conversion substrate 200. The second substrate 210 may be made of a transparent material. For example, the second substrate 210 may include a transparent substrate such as a sapphire substrate, glass, or the like. However, the disclosure is not limited thereto, and it may be formed of a conductive substrate such as GaN, SiC, ZnO, Si, GaP, and GaAs.

The bank layer BNL may be located on one surface of the second substrate 210. The bank layer BNL may surround the first emission area EA1, the second emission area EA2, and the third emission area EA3. The bank layer BNL may include portions extending in the first direction DR1 and the second direction DR2 to form a lattice pattern in the entire display area DPA. The bank layer BNL may also be located in the non-display area NDA, and may completely cover one surface of the second substrate 210 in the non-display area NDA.

The bank layer BNL may include, or define, a plurality of openings OP1, OP2, and OP3 exposing the second substrate 210 in the display area DPA. The plurality of openings OP1, OP2, and OP3 may include a first opening OP1 overlapping the first emission area EA1, a second opening OP2 overlapping the second emission area EA2, and a third opening OP3 overlapping the third emission area EA3. The plurality of openings OP1, OP2, and OP3 may correspond to the plurality of emission areas EA1, EA2, and EA3, respectively.

In some embodiments, the bank layer BNL may contain silicon (Si). For example, the bank layer BNL may include a silicon monocrystalline layer. The bank layer BNL containing silicon may be formed by a reactive ion etching (RIE) process. The bank layer BNL may be formed to have a relatively high aspect ratio by adjusting the process conditions of the etching process.

On one surface of the second substrate 210, the plurality of color filters CF1, CF2, and CF3 may be located in the plurality of openings OP1, OP2, and OP3 of the bank layer BNL, respectively. Different color filters CF1, CF2, and CF3 may be spaced apart from each other with the bank layer BNL interposed therebetween, but the disclosure is not limited thereto.

The plurality of color filters CF1, CF2, and CF3 may include a first color filter CF1, a second color filter CF2, and a third color filter CF3. The first color filter CF1 may be located in the first opening OP1 of the bank layer BNL to overlap the first emission area EA1. The second color filter CF2 may be located in the second opening OP2 of the bank layer BNL to overlap the second emission area EA2, and the third color filter CF3 may be located in the third opening OP3 of the bank layer BNL to overlap the third emission area EA3.

The plurality of color filters CF1, CF2, and CF3 may fill the openings OP1, OP2, and OP3, respectively, and respective surfaces of the color filters CF1, CF2, and CF3 may be in parallel with one surface of the bank layer BNL. That is, the thicknesses of the color filters CF1, CF2, and CF3 may be the same as the thickness of the bank layer BNL. However, the disclosure is not limited thereto, and respective surfaces of the color filters CF1, CF2, and CF3 may protrude from, or may be recessed from, the one surface of the bank layer BNL. That is, the thicknesses of the color filters CF1, CF2, and CF3 may be different from the thickness of the bank layer BNL.

The color filters CF1, CF2, and CF3 may be located in island-shaped patterns to correspond to the openings OP1, OP2, and OP3 of the bank layer BNL, respectively, but the disclosure is not limited thereto. For example, each of the color filters CF1, CF2, and CF3 may form a linear pattern extending in one direction in the display area DPA. In this case, the openings OP1, OP2, and OP3 of the bank layer BNL may also extend in one direction. In some embodiments, the first color filter CF1 may be a red color filter, the second color filter CF2 may be a green color filter, and the third color filter CF3 may be a blue color filter. Each of the color filters CF1, CF2, and CF3 may transmit some of the lights (e.g., some of the wavelengths of light) emitted from the light emitting element ED and passed through the color control structure WCL, and may block the transmission of other lights.

The second reflective layer RL2 may be located in the plurality of openings OP1, OP2, and OP3 of the bank layer BNL. The second reflective layer RL2 may be located on the side surface of the bank layer BNL, and may surround the side surfaces of the color filters CF1, CF2, and CF3 respectively located in the openings OP1, OP2, and OP3. The second reflective layer RL2 may be located in different openings OP1, OP2, and OP3 to surround different color filters CF1, CF2, and CF3, and the plurality of second reflective layers RL2 may be spaced apart from each other in the first direction DR1 and the second direction DR2 in a plan view.

The second reflective layer RL2 may reflect an incident light in a manner similar to the first reflective layer RL1. Some of the lights emitted from the light emitting element ED and incident on the color filters CF1, CF2, and CF3 may be reflected by the second reflective layer RL2, and may be emitted toward the top surface of the second substrate 210. The second reflective layer RL2 may contain the same material as that of the first reflective layer RL1, and may contain, for example, a metal material having high reflectivity, such as aluminum (Al). The thickness of the second reflective layer RL2 may be about 0.1 μm, but is not limited thereto.

The color control structure WCL may be located on the plurality of color filters CF1, CF2, and CF3. A plurality of color control structures WCL may overlap the first color filter CF1, the second color filter CF2, and the third color filter CF3, respectively, and may be spaced apart from each other. The color control structures WCL may respectively correspond to the plurality of openings OP1, OP2, and OP3 located in the bank layer BNL. In some embodiments, the color control structures WCL may overlap the plurality of openings OP1, OP2, and OP3, respectively. The color control structures WCL may form island-shaped patterns spaced apart from each other. However, the disclosure is not limited thereto, and the color control structures may form a linear pattern extending in one direction.

The color control structure WCL may change or shift the peak wavelength of the incident light to another corresponding peak wavelength to emit light of the corresponding peak wavelength. In the embodiments in which the light emitting element ED emits blue light of a third color, the color control structure WCL may change at least a part of the light emitted from the light emitting element ED to yellow light of a fourth color. A part of the light of the third color emitted from the light emitting element ED may be converted to the yellow light of the fourth color by the color control structure WCL, and the mixed light of the light of the third color and the light of the fourth color may be incident on each of the color filters CF1, CF2, and CF3. The first color filter CF1 may transmit the red light of the first color among the mixed light of the light of the third color and the light of the fourth color, and may block the transmission of the lights of other colors. Similarly, the second color filter CF2 may transmit the green light of the second color among the mixed light of the light of the third color and the light of the fourth color, and may block the transmission of the lights of other colors, and the third color filter CF3 may transmit the blue light of the third color among the mixed light of the light of the third color and the light of the fourth color, and may block the transmission of the lights of other colors.

Each of the color control structures WCL may contain a base resin BRS and wavelength conversion particles WCP. The base resin BRS may contain a transparent organic material. For example, the base resin BRS may contain epoxy resin, acrylic resin, cardo resin, or imide resin. The base resins BRS of the color control structures WCL may be made of the same material, but the disclosure is not limited thereto. The wavelength conversion particles WCP may be materials that convert the blue light of the third color into the yellow light of the fourth color. The wavelength conversion particles WCP may be quantum dots, quantum rods, or fluorescent substances. Examples of the quantum dot may include group IV nanocrystal, group II-VI compound nanocrystal, group III-V compound nanocrystal, group IV-VI nanocrystal, and a combination thereof.

Further, each of the color control structures WCL may further include a scatterer. The scatterer may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like.

The content of the wavelength conversion particles WCP contained in the color control structure WCL increases as the thickness of the color control structure WCL in the third direction DR3 increases, so that the light conversion efficiency of the color control structure WCL may be increased. The thickness of the color control structure WCL may be designed in consideration of the light conversion efficiency of the wavelength conversion particles WCP.

The protective layer PTF may be located on the bank layer BNL and the color control structure WCL to cover them. The protective layer PTF may be located across the entire display area DPA and the entire non-display area NDA. The protective layer PTF may protect the color control structure WCL in the display area DPA, and may flatten the stepped portion formed by the color control structure WCL.

The protective layer PTF may be located between the light emitting element ED and the color control structure WCL, and may reduce or prevent the likelihood of damage to the wavelength conversion particles WCP of the color control structure WCL due to the heat generated by the light emitting element ED. The protective layer PTF may contain an organic insulating material (e.g., epoxy resin, acrylic resin, cardo resin or imide resin).

An adhesive layer ADL may be located between the display substrate 100 and the color conversion substrate 200. The adhesive layer ADL may adhere the display substrate 100 and the color conversion substrate 200, and may be made of a transparent material to transmit the light emitted from the light emitting element ED. For example, the adhesive layer ADL may contain an acrylic material, a silicon material, a urethane material, or the like, and may contain a UV curable or a thermosetting material.

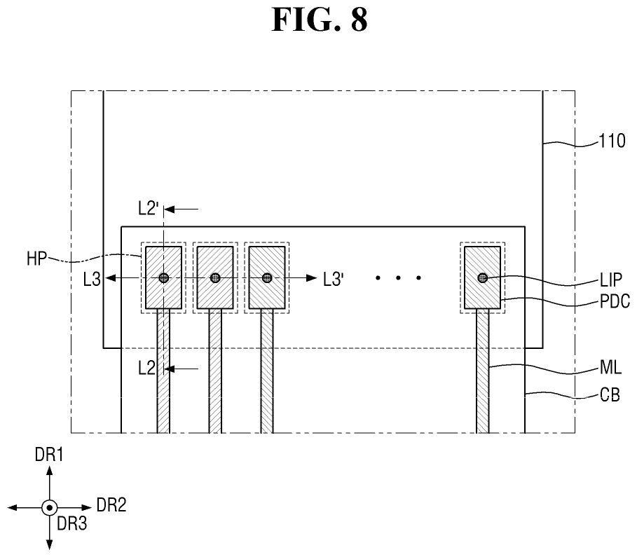

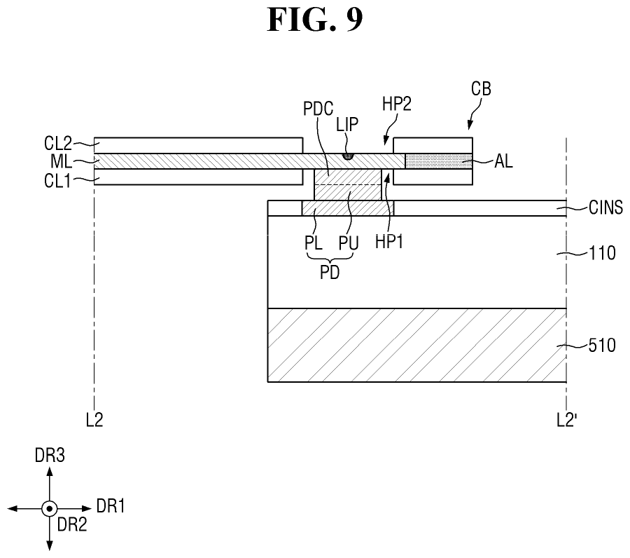

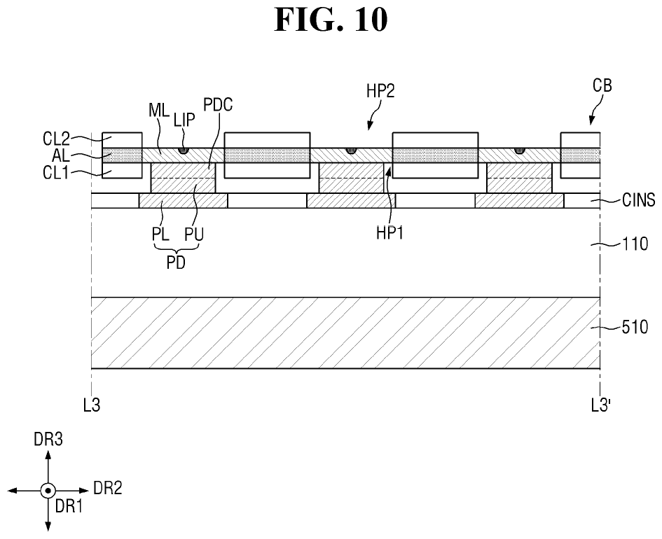

FIG. 8 is a plan view showing the region where circuit board pads of a display device according to some embodiments are located. FIG. 9 is a cross-sectional view taken along the line L2-L2′ of FIG. 8. FIG. 10 is a cross-sectional view taken along the line L3-L3′ of FIG. 8.

FIG. 8 shows a part of the circuit board CB located on the first substrate 110 in the pad area PDA located in the non-display area NDA of the display device 10. FIG. 8 schematically shows the planar arrangement of the circuit board pad PDC, a metal layer ML, and an opening hole HP located on the circuit board CB, and FIGS. 9 and 10 show cross sections of the circuit board pad PDC and the metal layer ML taken in the first direction DR1 and the second direction DR2, respectively.

Referring to FIGS. 8 to 10, in accordance with some embodiments, the circuit board CB of the display device 10 may include the metal layer ML and a plurality of circuit board pads PDC located on one surface of the metal layer ML. Further, the circuit board CB may include a plurality of cover layers CL1 and CL2 located on one surface and the other surface of the metal layer ML, and a circuit board adhesive layer AL for adhering them to each other.

The plurality of cover layers CL1 and CL2 may include a first cover layer CL1 and a second cover layer CL2 located on the first cover layer CL1. The circuit board CB may include a first surface facing the first substrate 110 and a second surface that is the top surface, which is opposite to the first surface. The first surface may be the bottom surface of the first cover layer CL1, and the second surface may be the top surface of the second cover layer CL2. The metal layer ML may be located on the top surface of the first cover layer CL1, and the second cover layer CL2 may be located on the metal layer ML so that the bottom surface of the second cover layer CL2 may be in contact with the metal layer ML. The shapes of the first cover layer CL1 and the second cover layer CL2 may be substantially the same as the shape of the circuit board CB. The plurality of cover layers CL1 and CL2 may protect the metal layer ML to which an electrical signal is applied. The cover layers CL1 and CL2 may be made of an insulating material, such as polyimide (PI). The plurality of cover layers CL1 and CL2 may be adhered to each other by the circuit board adhesive layer AL located therebetween.

The metal layer ML may be located between the cover layers CL1 and CL2. The metal layer ML may be electrically connected to the external device mounted on the circuit board CB, and may be electrically connected to the circuit board pad PDC. The electrical signal applied from the external device may be transmitted to the circuit board pad PDC and to the pads PD of the display substrate 100 through the metal layer ML.

The metal layer ML may be located on the circuit board CB in the form of a plurality of wires. The wires of the metal layer ML may have a shape extending in one direction, and may be electrically connected to the circuit board pads PDC at the ends of the portions of the circuit board CB that overlap the first substrate 110. Different wires of the metal layer ML may be connected to different circuit board pads PDC, and may be spaced apart from each other. Although it is illustrated in the drawing that the wires of the metal layer ML extend in the first direction DR1, the disclosure is not limited thereto. The arrangement of the wires of the metal layer ML may be designed to correspond to the number of circuit board pads PDC located on the circuit board CB and to correspond to the arrangement thereof. For example, when the plurality of circuit board pads PDC are not in parallel to each other, the wires of the metal layer ML may have different extension lengths, and the gap between the wires of the metal layer ML may be different depending on the positions of the circuit board pads PDC. The wires of the metal layer ML may also have a shape extending in one direction, and may be bent partially.

In accordance with some embodiments, in the circuit board CB of the display device 10, each of the cover layers CL1 and CL2 may include a plurality of opening holes HP (HP1 and HP2), and surfaces of the metal layer ML may be partially exposed to correspond to the opening holes HP1 and HP2, respectively. The first cover layer CL1 may be located on (e.g., below) one surface of the metal layer ML, and may include a plurality of first opening holes HP1 exposing a part of the one surface of the metal layer ML. The second cover layer CL2 may be located on the other surface of the metal layer ML, and may include a plurality of second opening holes HP2 exposing a part of the other surface of the metal layer ML. The plurality of opening holes HP (HP1 and HP2) may be formed to respectively correspond to the circuit board pads PDC located on the circuit board CB. The plurality of circuit board pads PDC may respectively correspond to the pads PD formed on the first substrate 110. In the embodiments in which the plurality of pads PD and the circuit board pads PDC are spaced apart from each other in the second direction DR2, the plurality of opening holes HP1 and HP2 may be spaced apart from each other in the second direction DR2 to correspond to the circuit board pads PDC. The first opening holes HP1 may be formed in the first cover layer CL1 to be spaced apart from each other in the second direction DR2, and the second opening holes HP2 may be formed in the second cover layer CL2 to be spaced apart from each other in the second direction DR2. However, the disclosure is not limited thereto, and the arrangement of the opening holes HP1 and HP2 may vary depending on the arrangement of the pads PD of the display substrate 100 and the circuit board pads PDC.

The plurality of circuit board pads PDC may be located on (e.g., below) one surface of the metal layer ML. The circuit board pad PDC may be located in the first opening hole HP1 of the first cover layer CL1, and may be located on one surface, of the two surfaces of the metal layer ML, that faces the first substrate 110. As described above, the circuit board pads PDC may be formed to correspond to the arrangement of the pads PD of the first substrate 110, and the arrangement of the circuit board pads PDC may vary depending on the layout design of the plurality of wires electrically connected to the light emitting elements ED of the display substrate 100, and depending on the layout design of the wires of the metal layer ML. Depending on the layout design of the plurality of wires, the plurality of circuit board pads PDC may be spaced apart from each other in a misaligned manner without being spaced apart from each other in the second direction DR2.

The plurality of circuit board pads PDC may be located on (e.g., below) one surface of the metal layer ML exposed by the first opening hole HP1. For example, the plurality of circuit board pads PDC may respectively correspond to the plurality of first opening holes HP1, and may be directly located on (e.g., may directly contact) one surface of the metal layer ML. One circuit board pad PDC may be located in one first opening hole HP1, and may be spaced apart from the circuit board pad PDC located in another first opening hole HP1. The circuit board pad PDC may be electrically connected to the metal layer ML and the pad PD of the display substrate 100. The circuit board pad PDC may be formed on one surface of the metal layer ML containing a conductive material and patterned on the first cover layer CL1. For example, the circuit board pad PDC may also be formed by the process of plating a conductive material, such as a metal, on one surface of the metal layer ML.

In accordance with some embodiments, the plurality of circuit board pads PDC may be formed integrally with the pads PD of the display substrate 100. The circuit board pads PDC may respectively correspond to the plurality of pads PD, and may be integrated with each other when respective materials thereof are melted in a state where they are bonded to each other. For example, the pad PD located on the first substrate 110 may include a pad base layer PL, and a pad upper layer PU located on the pad base layer PL, and the circuit board pad PDC may be integrated with the pad upper layer PU. As will be described later, in the display device 10, the pads PD of the display substrate 100 and the circuit board pads PDC of the circuit board CB may be bonded by the laser bonding process. When the heat is transferred by the irradiated laser, the materials of the pads PD and the circuit board pads PDC may be melted and integrated with each other. The pads PD and the circuit board pads PDC made of a metal material as a conductive material may be alloyed when the metal material is partially melted by the heat transferred by the laser. The pads PD and the circuit board pads PDC may be integrated with each other so that there is no physical interface.

Further, the laser irradiated in the manufacturing process of the display device 10 might not be directly irradiated to the circuit board pad PDC, and may be irradiated to the portion of the metal layer ML where the circuit board pad PDC is located. In accordance with some embodiments, in the display device 10, the laser for bonding the circuit board pads PDC and the pads PD may be irradiated to the other surface of the metal layer ML exposed by the second opening hole HP2, and a plurality of patterns LIP formed by the laser irradiation may be located on the other surface (e.g., upper surface) of the metal layer ML.

The plurality of patterns LIP may be formed on the other surface of the metal layer ML, and may be formed to overlap the circuit board pad PDC in the thickness direction. The other surface of the metal layer ML may be exposed by the second opening hole HP2 of the second cover layer CL2, and at least one pattern LIP may be located in the second opening hole HP2. In the drawing, it is illustrated that one pattern LIP is located in one second opening hole HP2 to correspond to one circuit board pad PDC. However, the disclosure is not limited thereto, and a plurality of patterns LIP may be located in one second opening hole HP2 to correspond to one circuit board pad PDC.

The pads PD of the display substrate 100 and the circuit board pads PDC of the circuit board CB may be melted, or partially melted, and integrated with each other by the laser bonding process. The laser might not be directly irradiated to the interface between the pads PD and the circuit board pads PDC, and may be irradiated to the metal layer ML where the circuit board pad PDC is located. When the laser is irradiated to the other surface of the metal layer ML where the circuit board pad PDC is not located, the heat generated by the laser may be transferred to the circuit board pad PDC through the metal layer ML, and the circuit board pads PDC and the pads PD of the display substrate 100 may be melted by the heat.

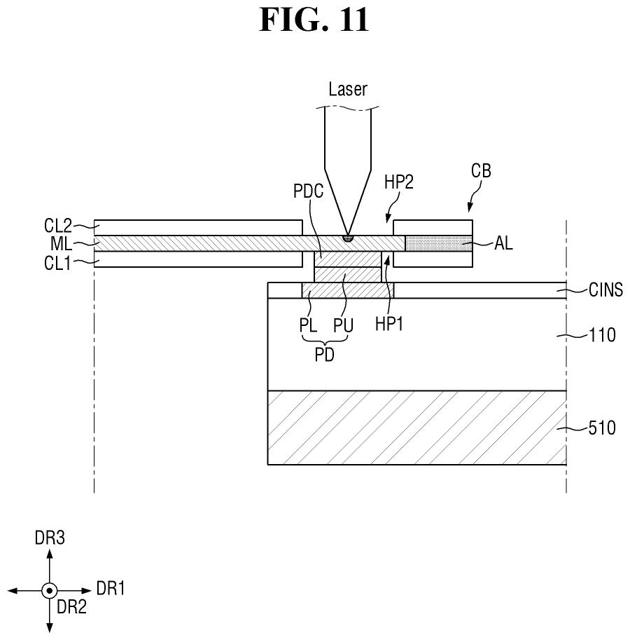

FIG. 11 is a schematic view showing a process of bonding pads and circuit board pads during the manufacturing process of a display device according to some embodiments.

Referring to FIG. 11, in the manufacturing process of the display device 10, the circuit board CB may be prepared such that the circuit board pads PDC are located on the pads of the first substrate 110 to correspond thereto. Each of the circuit board pads PDC may be directly located on the pad upper layer PU of the pad PD, and the bottom surface of the circuit board pad PDC may be in contact with the top surface of the pad upper layer PU.

In accordance with some embodiments, the process of bonding the circuit board pad PDC and the pad PD may be performed by the laser bonding process of bonding the pads by irradiating laser. The laser may be irradiated to the other surface of the metal layer ML exposed by the second opening hole HP2, and the heat generated by the irradiated laser may be transferred to the circuit board pad PDC through the metal layer ML. Of the two surfaces of the circuit board CB, the laser may be irradiated from the second surface of the circuit board CB that is opposite to the first surface, which faces the first substrate 110, and the second cover layer CL2 located on the metal layer ML may expose a part of the other (e.g., upper) surface of the metal layer ML, which is the region defining a portion of the second opening hole HP2, and to which the laser is irradiated. The laser may be irradiated only to the metal layer ML without being directly irradiated to the cover layers CL1 and CL2 made of a material having a relatively low melting point. The laser may transfer thermal energy capable of melting the circuit board pad PDC and the pad PD without damaging the cover layers CL1 and CL2 protecting the metal layer ML.

In some embodiments, the metal layer ML may be made of a conductive material, and a thermally conductive material, so that it is possible to apply an electrical signal to the circuit board pad PD, and to transfer the heat generated by the laser to the circuit board pad PDC. For example, the metal layer ML may be made of a metal material such as gold (Au), copper (Cu), aluminum (Al), and tin (Sn) and may be patterned on the first cover layer CL1. The metal layer ML may be made of a material having a melting point that is higher than those of the materials forming the cover layers CL1 and CL2 and the circuit board pad PDC. The metal layer ML may not be melted even when the circuit board pad PDC is melted by the laser.

The patterns LIP as the traces of the laser irradiation may remain on the other surface of the metal layer ML. The pattern LIP may be the portion where the other surface of the metal layer ML is partially carbonized or fused by the laser irradiation. Each of the patterns LIP may have a shape corresponding to the spot of the irradiated laser. The patterns LIP may be formed in the second opening hole HP2 to which the laser is irradiated, and may be spaced apart from the second cover layer CL2. By irradiating the laser without damaging the second cover layer CL2, the patterns LIP may be formed at positions spaced apart from the sidewalls of the second opening hole HP2. For example, the patterns LIP may substantially overlap the central portion of the circuit board pad PDC, and may be located at the central portion of the second opening hole HP2. However, the disclosure is not limited thereto, and the arrangement of the patterns LIP may vary depending on the laser irradiation position.

The circuit board pad PDC and the pad PD may be partially melted by the heat from the laser. The circuit board pad PDC and the pad PD may be partially fused and integrated with each other, or may be alloyed when the pads contain a metal material. The circuit board pad PDC and the pad PD may be connected to each other without a physical interface therebetween. Accordingly, the circuit board CB and the first substrate 110 may be firmly bonded by the laser bonding between the circuit board pads PDC and the pads PD, and the contact resistance that may occur due to the contact between different pads may be reduced.

Hereinafter, various embodiments of the display device 10 will be described with reference to other drawings.

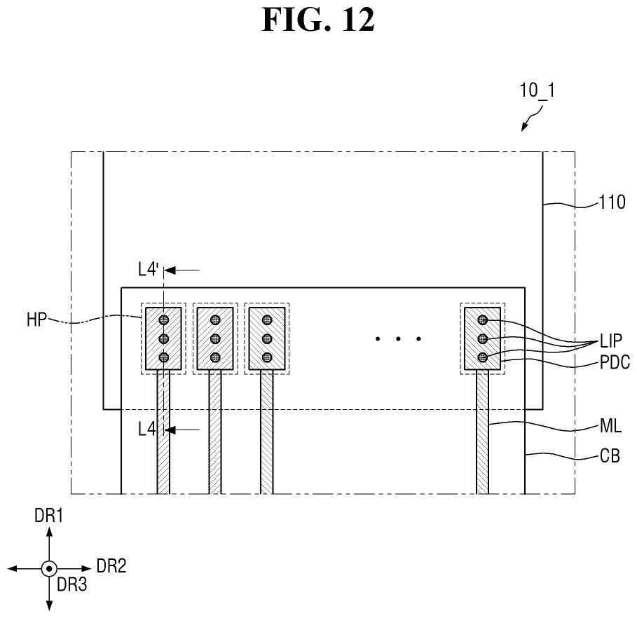

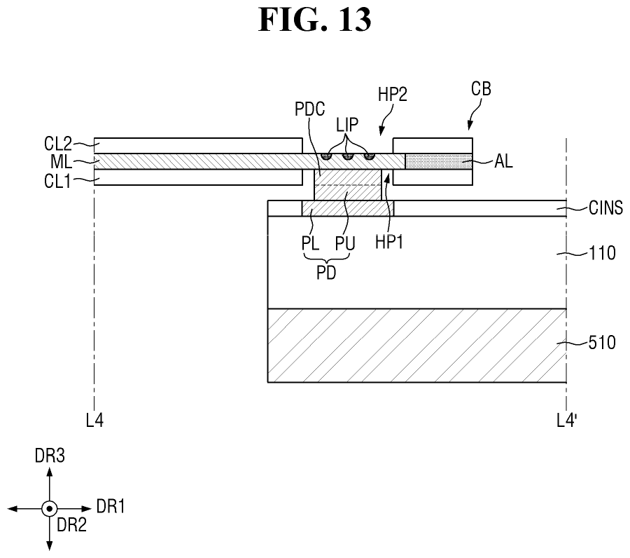

FIG. 12 is a plan view showing the region where the circuit board pads of a display device according to other embodiments are located. FIG. 13 is a cross-sectional view taken along the line L4-L4′ of FIG. 12.

Referring to FIGS. 12 and 13, a display device 10_1 may include a larger number of patterns LIP corresponding to the pads PD and the circuit board pads PDC. In accordance with some embodiments, in the circuit board CB of the display device 10_1, the plurality of patterns LIP may be located in the second opening hole HP2 corresponding to one circuit board pad PDC, and may be spaced apart from each other. These embodiments are different from the embodiments of FIGS. 8 and 9 with respect to the number of patterns LIP formed on the other surface of the metal layer ML. In the following description, redundant description will be omitted while focusing on differences.

In the display device 10_1, the laser may be irradiated to one circuit board pad PDC multiple times in the bonding process for bonding the circuit board pad PDC and the pad PD of the display substrate 100. When the laser is irradiated once, one pattern LIP may be formed to correspond to the spot of the laser. When the laser is irradiated multiple times to correspond to one circuit board pad PDC, the plurality of patterns LIP may be formed to respectively correspond to the laser spots. It is illustrated in the drawing that three patterns LIP are formed in one second opening hole HP2 (HP) to correspond to the circuit board pad PDC while being spaced apart from each other in the first direction DR1. In the laser irradiation process, the three patterns LIP may be formed by irradiating the laser three times to portions of the other surface of the metal layer ML in one second opening hole HP2 that are spaced apart from each other in the first direction DR1. However, the disclosure is not limited thereto, and the arrangement of the plurality of patterns LIP and the shapes thereof may be variously changed depending on the spot shape of the irradiated laser and the laser irradiation position.

The laser irradiation amount required to melt the circuit board pad PDC and the pad PD may vary depending on the output of a laser irradiation device, the area of the circuit board pad PDC, or the like. In the manufacturing process of the display device 10_1, after the laser is irradiated into the second opening hole HP2, the laser may be additionally irradiated in consideration of the bonding state of the circuit board pad PDC and the pad PD. Here, when the laser is irradiated again to the position to which the laser is irradiated first, the circuit board pad PDC and the metal layer ML may be damaged due to excessive energy transfer. Therefore, a plurality of lasers may be irradiated to different positions. Accordingly, the plurality of patterns LIP may be located in the second opening hole HP2 of the circuit board CB of the display device 10_1.

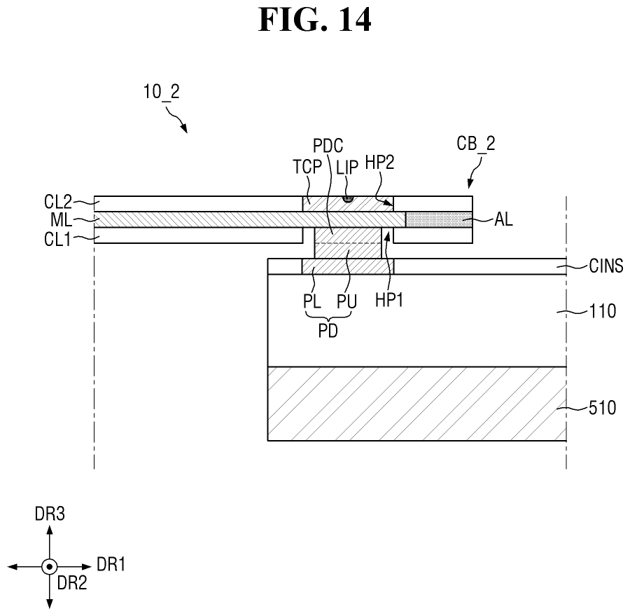

FIG. 14 is a cross-sectional view showing the portion where the circuit board and the pad of a display device according to other embodiments are located.

Referring to FIG. 14, a display device 10_2 according to some embodiments may include a heat transfer pattern TCP located in the second opening hole HP2 of the circuit board CB. The circuit board CB may include a plurality of heat transfer patterns TCP filling the second opening hole HP2 to protect the metal layer ML exposed by the second opening hole HP2. In the manufacturing process of the display device 10_2, the laser for bonding the circuit board pad PDC and the pad PD may be irradiated to the top surface of the heat transfer pattern TCP. The plurality of patterns LIP formed by the laser irradiation may be formed on the top surface of the heat transfer pattern TCP.

The heat transfer patterns TCP may contain a material having a relatively high thermal conductivity, and may transfer the heat generated by the laser irradiation to the metal layer ML and the circuit board pad PDC. For example, the heat transfer pattern TCP may be made of a metal material, or a polymer material having relatively high thermal conductivity. The heat transfer pattern TCP may be made of a material having a melting point that is higher than that of the circuit board pad PDC, and may transfer heat without, or with relatively little, shape deformation during the transfer of the energy that is sufficient to melt the circuit board pad PDC. In some embodiments, the metal layer ML may be completely protected by covering the second opening hole HP2 of the circuit board CB with the heat transfer patterns TCP.

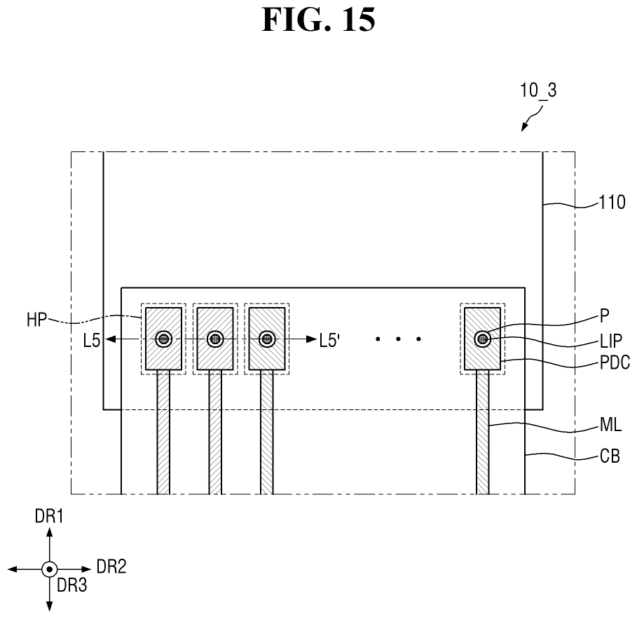

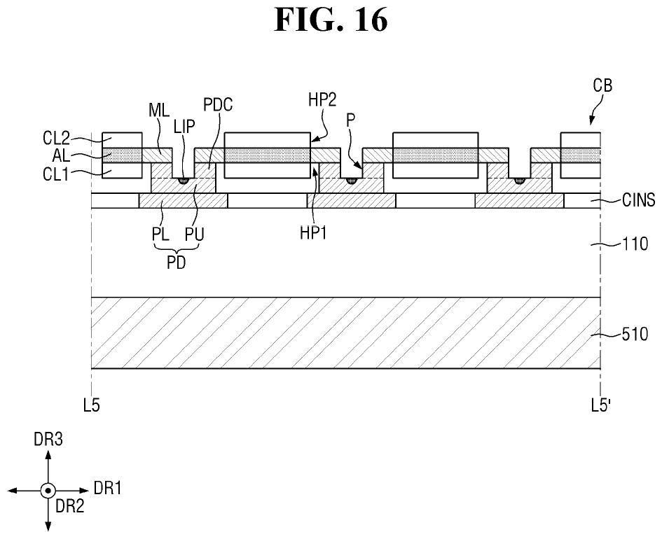

FIG. 15 is a plan view showing the region where the circuit board pads of a display device according to still other embodiments are located. FIG. 16 is a cross-sectional view taken along the line L5-L5′ of FIG. 15.

Referring to FIGS. 15 and 16, a display device 10_3 according to some embodiments may include a pin hole P penetrating the circuit board pad PDC, and the laser for bonding the circuit board pad PDC and the pad PD may be irradiated into the pin hole P. The laser may be directly irradiated to the top surface of the pad PD of the display substrate 100 through the pin hole P, and the pattern LIP as the trace of the laser irradiation may be formed on the top surface of the pad PD.

A plurality of pin holes P may be formed in the opening holes HP (HP1 and HP2) of the circuit board CB. The pin hole P may be formed to penetrate the metal layer ML and the circuit board pad PDC in the opening holes HP (HP1 and HP2). Even if the circuit board CB is located on the first substrate 110 of the display substrate 100, the top surface of the pad upper layer PU of the pad PD may be partially exposed through the first opening hole HP1, the second opening hole HP2, and the pin hole P.

In the manufacturing process of the display device 10_3, the laser may be directly irradiated to the pad PD of the display substrate 100 in the pin hole P. The laser irradiated to the pad PD may transfer the heat capable of melting the pad PD and the circuit board pad PDC. The pad PD and the circuit board pad PDC may be integrated with each other, or alloyed with each other, when they are melted at the peripheral portion of the pin hole P, and the pattern LIP as the trace of the laser irradiation may be formed in the region of the pad upper layer PU of the pad PD where the pin hole P is located. In some embodiments, the laser may be directly irradiated to the pad PD bonded to the circuit board pad PDC, and damage to other layers of the circuit board CB (e.g., the metal layer ML and the cover layers CL1 and CL2), may be reduced or prevented.

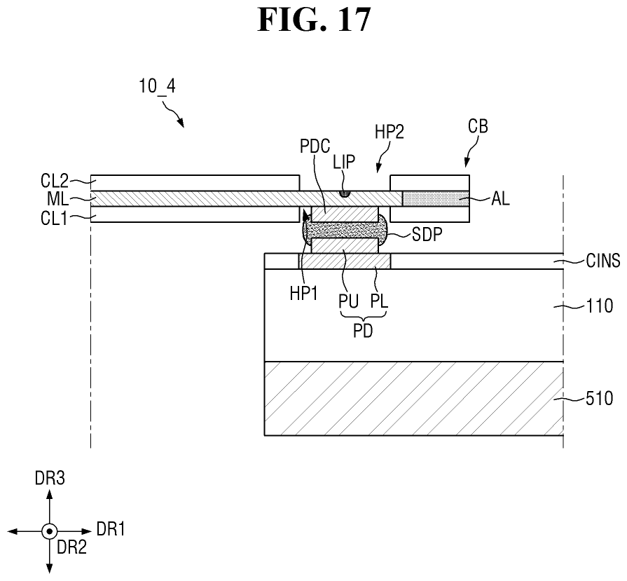

FIG. 17 is a cross-sectional view showing the portion where the pads and the circuit board pads of a display device according to still other embodiments are located.

Referring to FIG. 17, a display device 10_4 according to some embodiments may further include a soldering paste SDP located between the circuit board pad PDC and the pad PD of the display substrate 100. The soldering paste SDP may be made of a conductive organic material, and the circuit board pad PDC and the pad PD may be melted together with the soldering paste SDP and bonded to each other. These embodiments are different from the embodiments of FIG. 9 in that the circuit board CB may be bonded to the display substrate 100 through the soldering paste SDP between the pad PD and the circuit board pad PDC. In the following description, redundant description will be omitted.

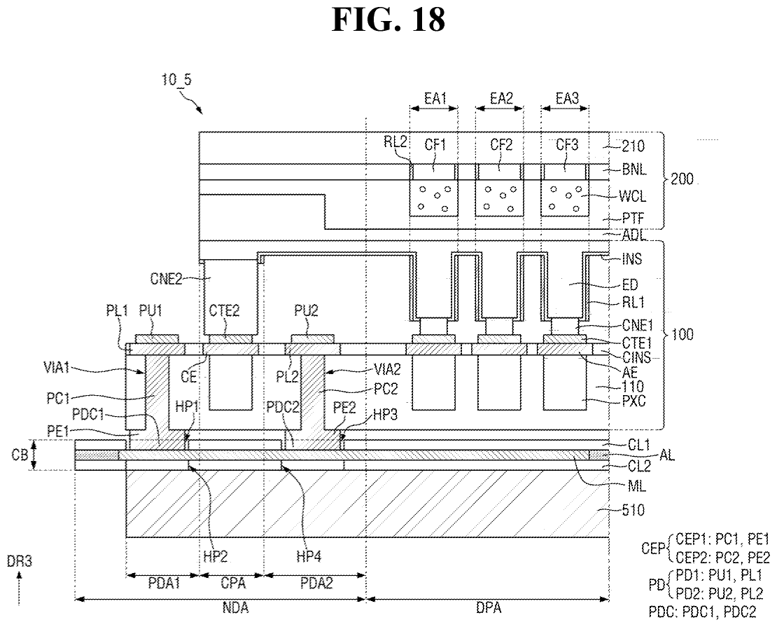

FIG. 18 is a cross-sectional view illustrating a part of a display device according to still other embodiments.

Referring to FIG. 18, in a display device 10_5 according to some embodiments, the circuit board CB may be located below the first substrate 110, and the plurality of pads PD (PD1 and PD2) in the non-display area NDA may be electrically connected to circuit board pads PDC1 and PDC2 of the circuit board CB through via holes VIA1 and VIA2 penetrating the first substrate 110. These embodiments are different from the embodiments of FIG. 4 with respect to the electrical connection type between the pads PD and the circuit board pads PDC1 and PDC2, and with respect to the arrangement of pad areas PDA1 and PDA2.

In the display device 10_5, it may be suitable to secure the space for the common electrode connection portion CPA and the pad area PDA in the non-display area NDA. The display device 10_5 may be designed to reduce or minimize the non-display area NDA to implement an ultra-high resolution display device by arranging a larger number of light emitting elements ED per unit area.

In the display device 10_5 according to some embodiments, the circuit board CB may be located below the first substrate 110, the plurality of pads PD may be electrically connected to the circuit board pads PDC through the via holes VIA1 and VIA2 penetrating the first substrate 110, and some of the plurality of pads PD may be located at the inside of the common electrode connection portion CPA. The plurality of pads PD may be located at the inside and the outside with respect to the common electrode connection portion CPA in the non-display area NDA, and the space of the outer region of the common electrode connection portion CPA may be reduced or minimized. In the display device 10, it is possible to reduce or minimize the outer region of the common electrode connection portion CPA in the non-display area NDA of the first substrate 110, and the display area DPA may occupy a relatively large area. In the display device 10 according to some embodiments, the pads PD are electrically connected to the circuit board pad PDC of the circuit board CB while penetrating the first substrate 110, so that it is possible to secure the sufficient space for the display area DPA, which is advantageous in implementing the ultra-high resolution display device.

The display device 10_5 may include the pad areas PDA (PDA1 and PDA2) located in the non-display area NDA (e.g., a first pad area PDA1 located at the outer side of the common electrode connection portion CPA, and a second pad area PDA2 located at the inner side of the common electrode connection portion CPA). With respect to the common electrode connection portion CPA, the first pad area PDA1 may be an outer pad area, and the second pad area PDA2 may be an inner pad area. The plurality of pads PD (PD1 and PD2) may be located in the first pad area PDA1 and the second pad area PDA2, respectively. The first pad PD1 and the second pad PD2 may be located at the outer side and the inner side, respectively, with respect to the common electrode CE. The first pad PD1 may include a first pad base layer PL1 and a first pad upper layer PU1, and the second pad PD2 may include a second pad base layer PL2 and a second pad upper layer PU2. The description of the structures of the pads PD is the same as the above description.

The plurality of pads PD (PD1 and PD2) may be electrically connected to the circuit board pads PDC (PDC1 and PDC2) of the circuit board CB through the plurality of via holes VIA (VIA1 and VIA2) formed in the first substrate 110, and through pad connection electrodes CEP (CEP1 and CEP2), respectively. The plurality of pads PD1 and PD2 may be located on one surface of the first substrate 110, and the circuit board pads PDC1 and PDC2 may be located on one surface of the circuit board CB. In accordance with some embodiments, the plurality of via holes VIA (VIA1 and VIA2) include a first via hole VIA1 formed in the first pad area PDA1 and a second via hole VIA2 formed in the second pad area PDA2 in the non-display area NDA. The plurality of pad connection electrodes CEP may include a first pad connection electrode CEP1 electrically connecting the first pad PD1 and the first circuit board pad PDC1 and a second pad connection electrode CEP2 electrically connecting the second pad PDC2 and the second circuit board pad PDC2.

The first via hole VIA1 may be formed to correspond to each of the first pads PD1 in the first pad area PDA1, and may penetrate the first substrate 110. The first via holes VIA1 may penetrate from one surface of the first substrate 110, where the first pads PD1 are located, to the other surface of the first substrate 110. The first via holes VIA1 may overlap the first pad PD1, and the first pad base layer PL1 may be located on the first via hole VIA1. A part of the first pad connection electrode CEP1 may be located in the first via hole VIA1, and may be electrically connected to each of the first pad PD1 and the first circuit board pad PDC1. The first pad connection electrode CEP1 may include a first connection portion PC1 located in the first via hole VIA1, and a first electrode portion PE1 located on the bottom surface of the first substrate 110 while being connected to the first connection portion PC1. The first connection portion PC1 may be in direct contact with the first pad base layer PL1 of the first pad PD1, and the first electrode portion PE1 may be located on the other surface of the first substrate 110 to be in direct contact with the first circuit board pad PDC1.

The second via hole VIA2 may be formed to correspond to each of the second pads PD2 in the second pad area PDA2, and may penetrate the first substrate 110. The second via holes VIA2 may penetrate from one surface of the first substrate 110, where the second pads PD2 are located, to the other surface of the first substrate 110. The second via holes VIA2 may overlap the second pad PD2, and the second pad base layer PL2 may be located on the second via hole VIA2. A part of the second pad connection electrode CEP2 may be located in the second via hole VIA2, and may be electrically connected to each of the second pad PD2 and the second circuit board pad PDC2. The second pad connection electrode CEP2 may include a second connection portion PC2 located in the second via hole VIA2, and a second electrode portion PE2 located on the bottom surface of the first substrate 110 while being connected to the second connection portion PC2. The second connection portion PC2 may be in direct contact with the second pad base layer PL2 of the second pad PD2, and the second electrode portion PE2 may be located on the other surface of the first substrate 110 to be in direct contact with the second circuit board pad PDC2.

The via holes VIA1 and VIA2 formed in the first substrate 110 may provide paths through which the pads PD1 and PD2 located on the first substrate 110 are electrically connected to the circuit board pad PDC through the pad connection electrode CEP. The first via holes VIA1 may correspond to the first pads PD1 in the first pad area PDA1, and the planar arrangement of the first via holes VIA1 may be substantially the same as the planar arrangement of the first pads PD1. The second via holes VIA2 may correspond to the second pads PD2 in the second pad area PDA2, and the planar arrangement of the second via holes VIA2 may be substantially the same as the planar arrangement of the second pads PD2.

The pad connection electrode CEP and the circuit board pad PDC may not completely correspond to the arrangement of the pads PD located on the first substrate 110. It is illustrated in the drawing that the first pad connection electrode CEP1 and the first circuit board pad PDC1 correspond to the first pad PD1 and the first via hole VIA1, respectively, and the second pad connection electrode CEP2 and the second circuit board pad PDC2 correspond to the second pad PD2 and the second via hole VIA2, respectively. However, the disclosure is not limited thereto, and the pads PD1 and PD2 and the circuit board pads PDC1 and PDC2 may not correspond to each other, respectively, and the circuit board pads PDC1 and PDC2 may correspond to some of the pads PD1 and PD2. Because the connection electrodes PC1 and PC2 are located in the via holes VIA1 and VIA2 to correspond thereto, respectively, the pad connection electrodes CEP1 and CEP2 may correspond to the pads PD located on the first substrate 110, and the electrode portions PE1 and PE2 may be in contact with the circuit board pads PDC1 and PDC2 while corresponding thereto, respectively. The pad connection electrode CEP and the circuit board pads PDC1 and PDC2 may be variously modified depending on the design of the pad PD and the structure of the first substrate 110.

The circuit board CB may include a first surface facing the bottom surface of the first substrate 110, and a second surface that is opposite to the first surface. The first surface of the circuit board CB may be the top surface of the first cover layer CL1, and the second surface may be the bottom surface of the second cover layer CL2. The first cover layer CL1 of the circuit board CB may include the first opening hole HP1 formed to correspond to the first circuit board pad PDC1 located in the first pad area PDA1, and a third opening hole HP3 formed to correspond to the second circuit board pad PDC2 located in the second pad area PDA2. Further, the second cover layer CL2 of the circuit board CB may include the second opening hole HP2 formed to correspond to the first circuit board pad PDC1 located in the first pad area PDA1, and a fourth opening hole HP4 formed to correspond to the second circuit board pad PDC2 located in the second pad area PDA2. The first circuit board pad PDC1 and the second circuit board pad PDC2 may be located on one surface of the metal layer ML in the first opening hole HP1 and the third opening hole HP3, respectively. The second opening hole HP2 and the fourth opening hole HP4 may partially expose the other surface of the metal layer ML where the circuit board pads PDC1 and PDC2 are located. The circuit board CB may include the plurality of opening holes HP1, HP2, HP3, and HP4 located in different pad areas PDA1 and PDA2 to correspond to the arrangement of the circuit board pads PDC1 and PDC2.

In some embodiments, the patterns LIP (see FIG. 9) may be formed by the laser irradiation on the other surface of the metal layer ML exposed by the second opening hole HP2 and the fourth opening hole HP4. The laser irradiated at the time of bonding the circuit board CB and the first substrate 110 may be irradiated from the second surface of the circuit board CB, and may be irradiated to the metal layer ML exposed by the second opening hole HP2 and the fourth opening hole HP4.

The circuit board pads PDC1 and PDC2 and the electrode portions PE1 and PE2 of the pad connection electrodes CEP1 and CEP2 may be integrated and bonded to each other by the irradiated laser. The first circuit board pad PDC1 may be integrated with the first electrode portion PE1 of the first pad connection electrode CEP1, and the second circuit board pad PDC2 may be integrated with the second electrode portion PE2 of the second pad connection electrode CEP2.

The heat dissipation substrate 510 may be located below the circuit board CB. The heat dissipation substrate 510 may be in direct contact with the bottom surface of the circuit board CB or the bottom surface of the second cover layer CL2. The heat dissipation substrate 510 may be in contact with the circuit board CB to transfer or release the heat generated by the circuit board CB and the display substrate 100.

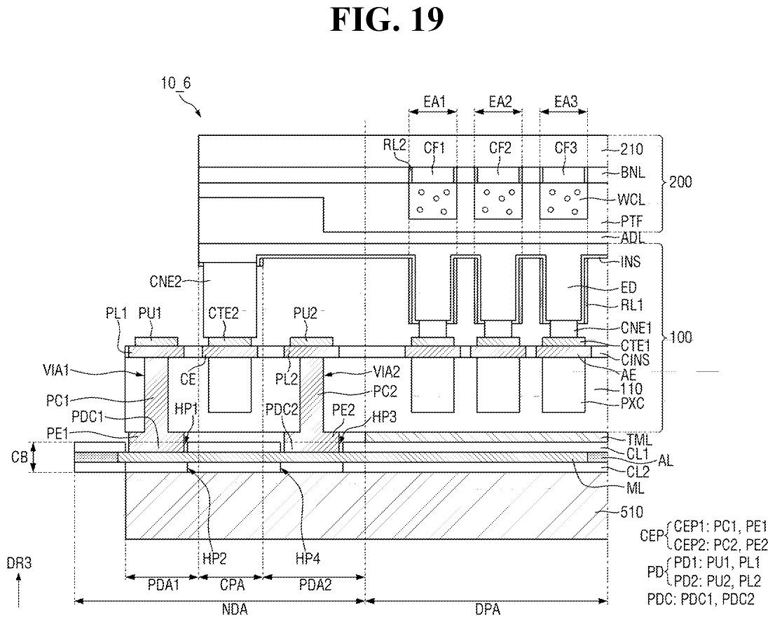

FIG. 19 is a cross-sectional view illustrating a part of a display device according to other embodiments.

Referring to FIG. 19, a display device 10_6 according to some embodiments may further include a heat dissipation layer TML located between the first substrate 110 and the heat dissipation substrate 510. The heat dissipation layer TML may contain a material having high thermal conductivity, and may be located below the first substrate 110 to effectively dissipate the heat generated by the display device 10_6. The display device 10_6 of these embodiments is different from the embodiments of FIG. 17 in that it further includes the heat dissipation layer TML. In the following description, redundant description will be omitted while focusing on differences.

The heat dissipation layer TML may contain substantially the same material as that of the heat dissipation substrate 510, and may be located between the circuit board CB and the first substrate 110. In some embodiments, the heat dissipation layer TML may be directly located on the bottom surface of the first substrate 110 in the region corresponding to the display area DPA. One surface of the heat dissipation layer TML may be in direct contact with the bottom surface of the first substrate 110, and the other surface of the heat dissipation layer TML may be in direct contact with one surface of the circuit board CB. In some embodiments, the heat dissipation layer TML may have the planar shape that is similar to that of the first substrate 110, and may have the area enough to cover at least the display area DPA.

Unlike the embodiments of FIG. 17, the space between the first substrate 110 and the circuit board CB may be filled with the heat dissipation layer TML, and the heat conduction may be further improved by the heat dissipation layer TML. Because the heat dissipation layer TML is in direct contact with the first substrate 110, it is possible to effectively release the heat generated by the light emitting elements ED and the pixel circuit units PXC located in the display area DPA. The heat dissipation layer TML may be the path through which the heat generated by the plurality of light emitting elements ED, and generated by the pixel circuit units PXC located in the display area DPA, is transferred to the heat dissipation substrate 510. The heat generated by the light emitting elements ED and the pixel circuit units PXC may be transferred to the heat dissipation layer TML, and the heat dissipation layer TML may release the heat through the circuit board CB and the heat dissipation substrate 510. In some embodiments, the display device 10_6 may include the heat dissipation layer TML, and may effectively release the heat generated by the display substrate 100, so that it is possible to reduce or prevent damage to the light emitting elements ED and the pixel circuit units PXC caused by the heat, and so that it is also possible to improve driving efficiency.

On the other hand, a display device for displaying an image according to some embodiments may be applied to various apparatuses and devices.

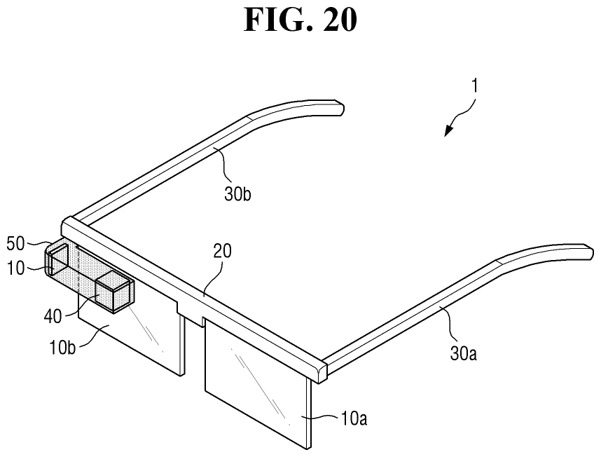

FIGS. 20 to 22 are schematic views showing a device including a display device according to some embodiments.

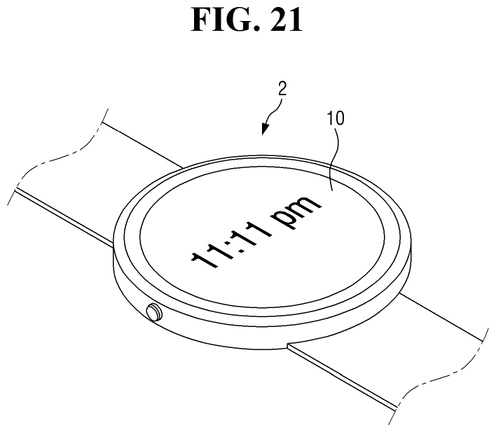

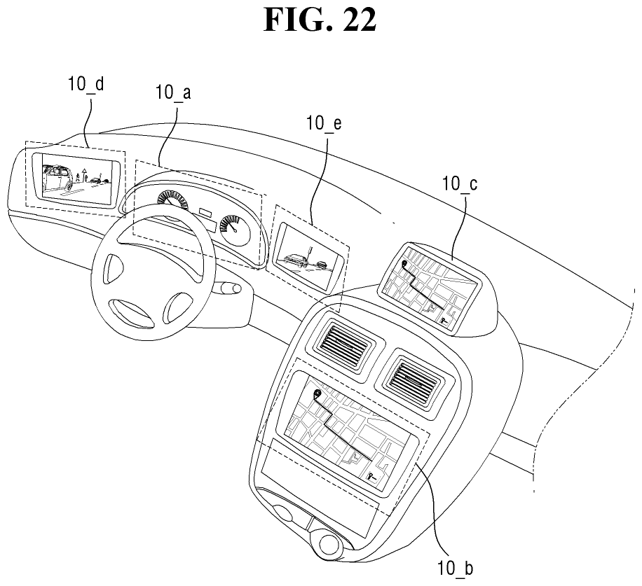

FIG. 20 shows a virtual reality device 1 to which the display device 10 according to some embodiments is applied, and FIG. 21 shows a smart watch 2 to which the display device 10 according to some embodiments is applied. FIG. 22 shows that display devices 10_a, 10_b, 10_c, 10_d, and 10_e according to some embodiments are applied to the display unit of an automobile.

Referring to FIG. 20, the virtual reality device 1 according to some embodiments may be a glasses-type device. The virtual reality device 1 according to some embodiments may include the display device 10, a left lens 10a, a right lens 10b, a support frame 20, temples 30a and 30b, a reflection member 40, and a display device storage 50.

Although the virtual reality device 1 including the temples 30a and 30b is illustrated, the virtual reality device 1 according to some embodiments may be applied to a head mounted display including a head mounted band that may be worn on a head, instead of the temples 30a and 30b. The virtual reality device 1 according to some embodiments is not limited to the structure shown in the drawing, and may be applied in various forms to various electronic devices.

The display device storage 50 may include the display device 10 and the reflection member 40. The image displayed on the display device 10 may be reflected by the reflection member 40, and provided to a user's right eye through the right lens 10b. Accordingly, the user can view the virtual reality image displayed on the display device 10 through the right eye.

The display device storage 50 may be, but is not necessarily, located at the right end of the support frame 20. For example, the display device storage 50 may be located at the left end of the support frame 20, and the image displayed on the display device 10 may be reflected by the reflection member 40, and provided to a user's left eye through the left lens 10a. Accordingly, the user can view the virtual reality image displayed on the display device 10 through the left eye. Alternatively, the display device storage 50 may be located at both the left end and the right end of the support frame 20. In that case, the user can view the virtual reality image displayed on the display device 10 through both the left eye and the right eye.

Referring to FIG. 21, the display device 10 according to some embodiments may be applied to the smart watch 2 that is one of the smart devices.

Referring to FIG. 22, the display devices 10_a, 10_b, and 10_c according to some embodiments may be applied to the dashboard of the automobile, the center fascia of the automobile, or the center information display (CID) of the dashboard of the automobile. Further, the display devices 10_d and 10_e according to some embodiments may be applied to a room mirror display instead of side mirrors of the automobile.

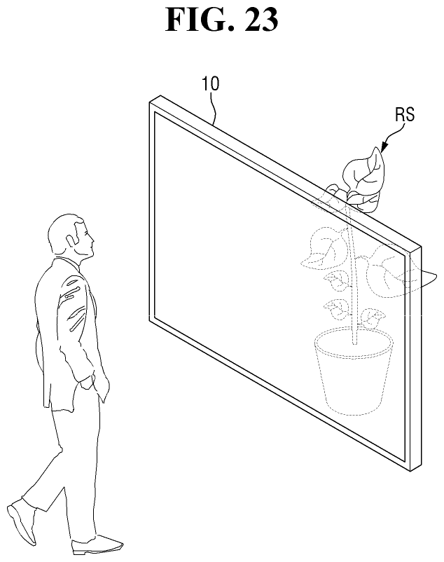

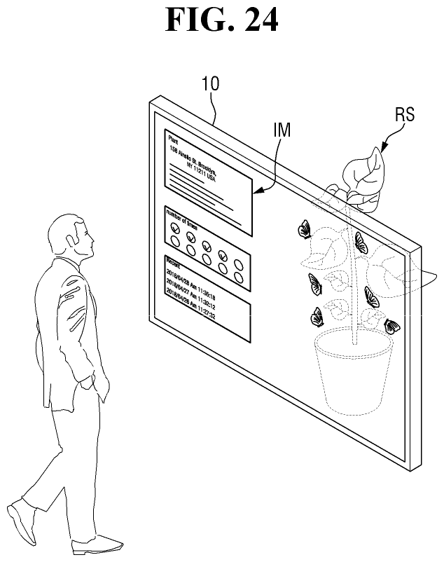

FIGS. 23 and 24 show a transparent display device including a display device according to some embodiments.

Referring to FIGS. 23 and 24, the display device 10 according to some embodiments may be applied to the transparent display device. The transparent display device may display an image IM, and also may transmit light. A user located on the front side of the transparent display device can view an object RS or a background on the rear side of the transparent display device as well as the image IM displayed on the display device 10. When the display device 10 is applied to the transparent display device, the first substrate 110, the heat dissipation substrate 510, and the circuit board CB of the display device 10 may include a light transmitting portion capable of transmitting light or may be made of a material capable of transmitting light.

In concluding the detailed description, those skilled in the art will appreciate that many variations and modifications can be made to the disclosed embodiments without substantially departing from the aspects of the present disclosure. Therefore, the embodiments of the present disclosure are used in a generic and descriptive sense only and not for purposes of limitation. Hence, the scope of the present disclosure is to be determined in accordance with the following claims, with functional equivalents thereof to be included therein, and should not be limited by the foregoing description.

What is claimed is:

1. A display device comprising:
a first substrate comprising a display area, and a non-display area surrounding the display area;
light emitting elements in the display area on the first substrate;
pads in the non-display area; and
a circuit board comprising circuit board pads connected to the pads, and comprising:
a first cover layer facing the first substrate, and defining first opening holes formed to correspond to the circuit board pads;
a metal layer on the first cover layer and having the circuit board pads therebelow; and
a second cover layer on the metal layer, and defining second opening holes exposing a portion of the metal layer.

2. The display device of claim 1, wherein the pads comprise pad base layers, and pad upper layers respectively on the pad base layers, and
wherein the circuit board pads are respectively integrated with the pad upper layers.

3. The display device of claim 2, further comprising patterns corresponding to the second opening holes, and overlapping the circuit board pads on the metal layer.

4. The display device of claim 3, wherein the patterns are in the second opening holes, respectively.

5. The display device of claim 2, further comprising a heat transfer pattern corresponding to the second opening holes, and directly contacting the metal layer.

6. The display device of claim 5, further comprising patterns on a portion of the heat transfer pattern overlapping the circuit board pads.

7. The display device of claim 2, wherein the circuit board defines pin holes corresponding to the second opening holes, and penetrating the metal layer and the circuit board pads.

8. The display device of claim 7, further comprising patterns on portions of the pad upper layers overlapping the pin holes, respectively,
wherein the pads and the circuit board pads are integrated with each other at a peripheral portion of the pin holes, respectively.

9. The display device of claim 1, further comprising common electrodes in the non-display area on the first substrate, and electrically connected to the light emitting elements, respectively,
wherein the pads respectively comprise first pads at outer sides of the common electrodes, and second pads at inner sides of the common electrodes in the non-display area,
wherein the first substrate defines first via holes penetrating therethrough, and respectively corresponding to the first pads, and also defines second via holes respectively corresponding to the second pads, and
wherein the display device further comprises first pad connection electrodes respectively connected to the first pads and to first circuit board pads of the circuit board pads, and second pad connection electrodes respectively connected to the second pads and to second circuit board pads of the circuit board pads.

10. The display device of claim 9, wherein the circuit board is below the first substrate,
wherein the first pad connection electrodes comprise first connection portions in the first via holes, respectively, and first electrode portions below the first substrate,
wherein the second pad connection electrodes comprise second connection portions in the second via holes, respectively, and second electrode portions below the first substrate,
wherein the first circuit board pads are integrated with the first electrode portions, respectively, and
wherein the second circuit board pads are integrated with the second electrode portions, respectively.

11. The display device of claim 1, further comprising a heat dissipation substrate below the first substrate, and located across the display area and the non-display area.

12. The display device of claim 11, wherein the circuit board further comprises a heat dissipation layer below the first substrate, and located between the first substrate and the circuit board in the display area.

13. The display device of claim 1, wherein the light emitting elements comprise first semiconductor layers, active layers on the first semiconductor layers, and second semiconductor layers on the active layers, and
wherein the display device further comprises a third semiconductor layer on the first substrate, and having the second semiconductor layers of the light emitting elements thereon, and common electrodes on the second semiconductor layers, respectively.

14. The display device of claim 13, wherein the second semiconductor layers of the light emitting elements are connected to each other through a base layer in the display area and the non-display area on the third semiconductor layer, and
wherein the display device further comprises first connection electrodes respectively between the light emitting elements and the first substrate in the display area, and second connection electrodes respectively between the common electrodes and the second semiconductor layers in the non-display area.

15. A display device comprising:
a first substrate comprising a display area on which light emitting elements are located, and a non-display area surrounding the display area;
common electrodes surrounding the display area in the non-display area, and spaced apart from each other;
pads spaced apart from the common electrodes in the non-display area; and
a circuit board comprising:
circuit board pads on the first substrate, and electrically connected to the pads, respectively,
cover layers; and
a metal layer between the cover layers, and having the circuit board pads therebelow,
wherein the cover layers define opening holes exposing respective portions of the metal layer.

16. The display device of claim 15, further comprising patterns in the opening holes, and overlapping the circuit board pads.

17. The display device of claim 16, wherein the patterns are in one of the opening holes.

18. The display device of claim 15, wherein the circuit board is on the first substrate on which the light emitting elements are located, and
wherein the circuit board pads are respectively integrated with the pads.

19. The display device of claim 15, wherein the circuit board is below the first substrate, and
wherein the pads are respectively electrically connected to the circuit board pads through pad connection electrodes in via holes penetrating the first substrate.

20. The display device of claim 19, wherein the pad connection electrodes respectively comprise connection portions in the via holes, and electrode portions respectively connected to the connection portions and located below the first substrate, and
wherein the circuit board pads are respectively integrated with the electrode portions of the pad connection electrodes.
